(19) United States
(12) Patent Application Publication
(10) Pub. No.: US 2026/0282677 A1
(43) Pub. Date: Sep. 17, 2026

(54) DISPLAY DEVICE AND ELECTRONIC DEVICE

(71) Applicant: Samsung Display Co., Ltd., Yongin-si (KR)

(72) Inventors: Yong Hee LEE, Yongin-si (KR); Kyung Bae KIM, Yongin-si (KR); Dong Woo KIM, Yongin-si (KR); Yeon Kyung KIM, Yongin-si (KR)

(21) Appl. No.: 19/429,074

(22) Filed: Dec. 22, 2025

(30) Foreign Application Priority Data
Mar. 11, 2025 (KR) 10-2025-0031185

(51) Int. Cl. H10K 59/131; H10K 59/121

(52) U.S. Cl. CPC H10K 59/131; H10K 59/1213

(57) ABSTRACT

A display device includes a substrate, a transistor above the substrate, a scan line connected to the transistor, a first electrode above the scan line, a light-emitting stack above the first electrode, a second electrode above the light-emitting stack, and an auxiliary line at a different layer from the scan line, and connected to the scan line.

### CROSS-REFERENCE TO RELATED APPLICATION

The present application claims priority to, and the benefit of, Korean Patent Application No. 10-2025-0031185, filed on Mar. 11, 2025, in the Korean Intellectual Property Office, the entire disclosure of which is incorporated herein by reference.

### BACKGROUND

### 1. Field

The present disclosure relates to a display device and an electronic device in which a voltage drop of a scan line may be reduced or minimized.

### 2. Description of the Related Art

A head-mounted display (HMD) is an image display device that is worn on a user’s head in the form of glasses or a helmet and focuses on a distance close to the user’s eyes. The head-mounted display may realize virtual reality (VR) or augmented reality (AR).

The head-mounted display enlarges and displays an image displayed on a small display device using a plurality of lenses. Therefore, a display device applied to the head-mounted display may suitably provide a high-resolution image, for example, an image having a resolution of about 3000 pixels per inch (PPI) or higher. To this end, organic light-emitting diode on silicon (OLEDoS), which is a high-resolution small-sized organic light-emitting display device, is used as the display device applied to the head-mounted display. The OLEDoS is a device that displays an image by disposing an organic light-emitting diode (OLED) on a semiconductor wafer substrate on which a complementary metal oxide semiconductor (CMOS) is located.

### SUMMARY

Aspects of the present disclosure provide a display device and an electronic device in which a voltage drop of a scan line may be reduced or minimized.

According to an aspect of the present disclosure, there is provided a display device including a substrate, a transistor above the substrate, a scan line connected to the transistor, a first electrode above the scan line, a light-emitting stack above the first electrode, a second electrode above the light-emitting stack, and an auxiliary line at a different layer from the scan line, and connected to the scan line.

The auxiliary line may be above the scan line.

The display device may further include a first insulating layer above the transistor, a second insulating layer above the first insulating layer, and a third insulating layer above the second insulating layer.

The scan line may be above the first insulating layer, wherein the auxiliary line is above the third insulating layer to overlap the scan line.

The display device may further include a middle connection electrode above the second insulating layer between the scan line and the auxiliary line, and connected to the scan line and to the auxiliary line.

The display device may further include a first via electrode penetrating through the first insulating layer and connected to a gate electrode of the transistor and to the scan line, a second via electrode penetrating through the second insulating layer and connected to the scan line and to the middle connection electrode, and a third via electrode penetrating through the third insulating layer and connected to the middle connection electrode and to the auxiliary line.

The display device may further include a capacitor electrode at a same layer as the auxiliary line.

The display device may further include a driving connection electrode and an anode connection electrode at a same layer as the auxiliary line.

The auxiliary line may be between the driving connection electrode and the anode connection electrode in plan view.

The display device may further include a capacitor electrode at the same layer as the auxiliary line.

The auxiliary line may include a plurality of auxiliary lines at different respective layers.

The display device may further include a first insulating layer above the transistor, a second insulating layer above the first insulating layer, a third insulating layer above the second insulating layer, and a fourth insulating layer above the third insulating layer.

The scan line may be above the first insulating layer, wherein the auxiliary line includes a first auxiliary line above the third insulating layer to overlap the scan line, and a second auxiliary line above the fourth insulating layer to overlap the first auxiliary line.

The display device may further include a middle connection electrode above the second insulating layer between the scan line and the first auxiliary line, and connected to the scan line and to the first auxiliary line.

The display device may further include a first via electrode penetrating through the first insulating layer and connected to a gate electrode of the transistor and to the scan line, a second via electrode penetrating through the second insulating layer and connected to the scan line and to the middle connection electrode, a third via electrode penetrating through the third insulating layer and connected to the middle connection electrode and to the first auxiliary line, and a fourth via electrode penetrating through the fourth insulating layer and connected to the first auxiliary line and to the second auxiliary line.

The display device may further include a fifth insulating layer above the fourth insulating layer.

The auxiliary line may further include a third auxiliary line above the fifth insulating layer to overlap the second auxiliary line.

The display device may further include a fifth via electrode penetrating through the fifth insulating layer and connected to the second auxiliary line and to the third auxiliary line.

According to another aspect of the present disclosure, there is provided an electronic device including a display device including a substrate, a transistor above the substrate, a scan line connected to the transistor, a first electrode above the scan line, a light-emitting stack above the first electrode, a second electrode above the light-emitting stack, and an auxiliary line at a different layer from the scan line and connected to the scan line.

The electronic device may include a smartphone, a tablet, a laptop, a TV, a desk monitor, a smart glasses, a smart watch, a head-mounted display, or a vehicle.

According to the display device and the electronic device according to one or more embodiments, the voltage drop of the scan line may be reduced or minimized.

For example, according to one or more embodiments, the auxiliary line may be connected to the bias scan line on the scan line. Therefore, the area of the scan line may be increased. Therefore, even if a length of the scan line becomes longer in a large-area display device, the voltage drop of the bias scan line may be reduced or minimized. Accordingly, distortion of the bias scan signal transmitted through the scan line may be reduced or minimized.

In addition, according to one or more embodiments, because the auxiliary line and the scan line are located on different respective layers so as to overlap in the vertical direction, the present disclosure may also be applied to a high-resolution display device with small-area pixels in the horizontal direction.

The aspects of the present disclosure are not limited to the above-described effects and other aspects that are not described herein will become apparent to those skilled in the art from the following description.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view illustrating a display device according to one or more embodiments;

FIG. 2 is a block diagram illustrating the display device according to one or more embodiments;

FIG. 3 is an equivalent circuit diagram of a first pixel according to one or more embodiments;

FIG. 4 is a layout view illustrating an example of a display panel according to one or more embodiments;

FIGS. 5 and 6 are layout views illustrating examples of a display area of FIG. 4;

FIG. 7 is a cross-sectional view illustrating an example of the display panel taken along the line I1-I1’ of FIG. 5;

FIG. 8 is a layout view of transistors of the display device according to one or more embodiments;

FIG. 9 is a layout view of a first conductive layer;

FIG. 10 is a view for describing a connection relationship between the transistors of FIG. 8 and the first conductive layer of FIG. 9;

FIG. 11 is a layout view of a second conductive layer;

FIG. 12 is a layout view of a third conductive layer;

FIG. 13 is a layout view of a fourth conductive layer;

FIG. 14 is a layout view of a fifth conductive layer;

FIG. 15 is a layout view of a sixth conductive layer;

FIG. 16 is a layout view of a seventh conductive layer;

FIG. 17 is a layout view of an eighth conductive layer;

FIG. 18 is a cross-sectional view of a display device according to one or more embodiments;

FIG. 19 is a cross-sectional view of a display device according to another embodiment;

FIG. 20 is a cross-sectional view of a display device according to another embodiment;

FIG. 21 is a block diagram of an electronic device according to one or more embodiments; and

FIGS. 22, 23, and 24, are schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

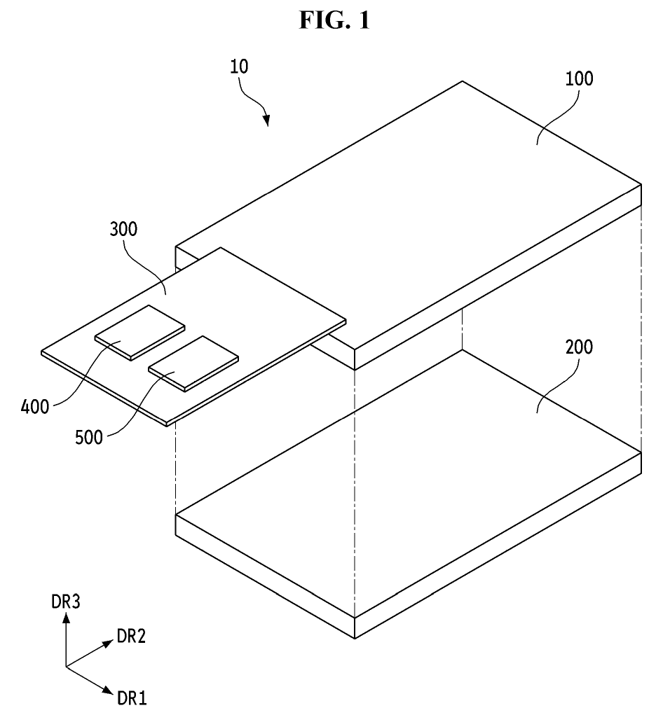

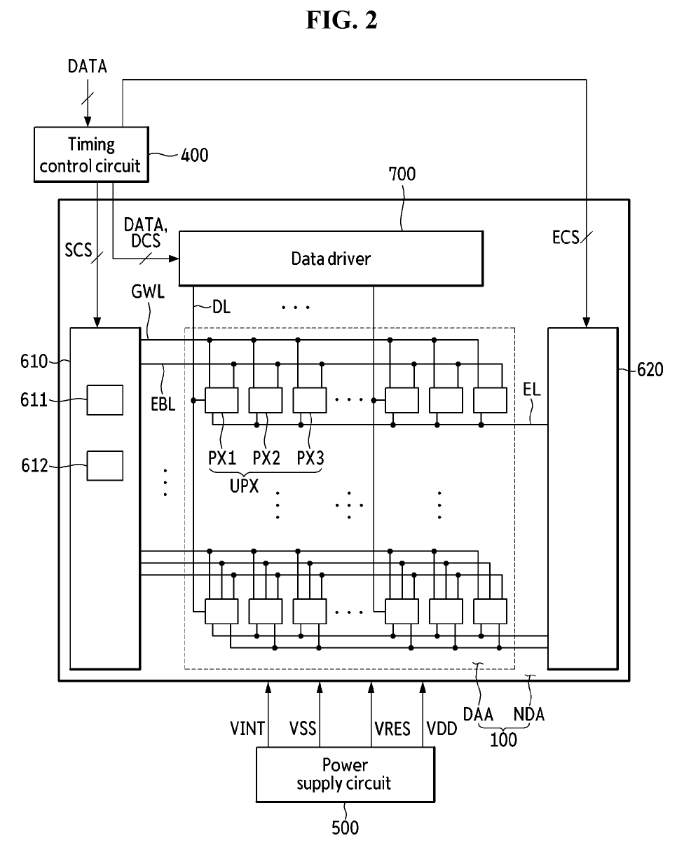

FIG. 1 is an exploded perspective view illustrating a display device according to one or more embodiments. FIG. 2 is a block diagram illustrating the display device according to one or more embodiments.

Referring to FIGS. 1 and 2, a display device 10 according to one or more embodiments is a device displaying a moving image or a still image. The display device 10 according to one or more embodiments may be applied to portable electronic devices such as a mobile phone, a smart phone, a tablet personal computer (PC), a mobile communication terminal, an electronic notebook, an electronic book, a portable multimedia player (PMP), navigation, and an ultra-mobile PC (UMPC). For example, the display device 10 according to one or more embodiments may be applied to a display unit of a television, a laptop computer, a monitor, a billboard, or the Internet of Things (IoT). Alternatively, the display device 10 according to one or more embodiments may be applied to a smart watch, a watch phone, and a head-mounted display (HMD) for implementing virtual reality and augmented reality.

The display device 10 according to one or more embodiments includes a display panel 100, a heat dissipation layer 200, a circuit board 300, a timing control circuit 400, and a power supply circuit 500.

The display panel 100 may be formed in a planar shape similar to a quadrangle. For example, the display panel 100 may have a planar shape similar to a quadrangle having short sides in a first direction DR1 and long sides in a second direction DR2 crossing the first direction DR1. In the display panel 100, a corner where the short side in the first direction DR1 and the long side in the second direction DR2 meet may be rounded to have a curvature or may be formed at a right angle. The planar shape of the display panel 100 is not limited to the quadrangle, and may be formed similarly to other polygons, circles, or ovals. A planar shape of the display device 10 may follow the planar shape of the display panel 100, but the present specification is not limited thereto.

As illustrated in FIG. 2, the display panel 100 includes a display area DAA displaying an image and a non-display area NDA that does not display an image.

The display area DAA includes a plurality of pixels PX1, PX2, and PX3, a plurality of scan lines GWL and EBL, a plurality of emission control lines EL, and a plurality of data lines DL. Here, three adjacent pixels PX1, PX2, and PX3 may form one unit pixel UPX.

The plurality of pixels PX1, PX2, and PX3 may be arranged in a matrix form in the first direction DR1 and the second direction DR2. The plurality of scan lines GWL and EBL and the plurality of emission control lines EL may extend in the first direction DR1 and may be located in the second direction DR2. The plurality of data lines DL may extend in the second direction DR2 and may be located in the first direction DR1.

The plurality of scan lines GWL and EBL include a plurality of write scan lines GWL and a plurality of bias scan lines GBL.

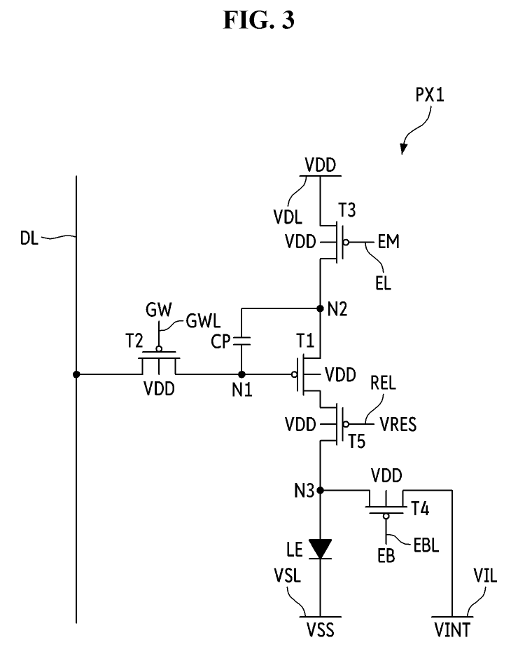

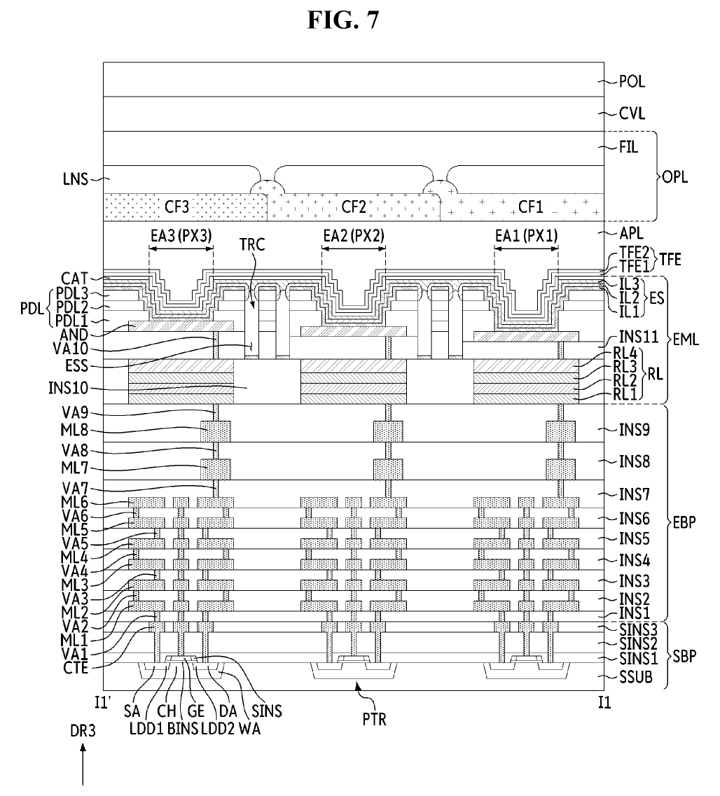

The plurality of pixels PX1, PX2, and PX3 may include a plurality of pixel transistors as illustrated in FIG. 3, and the plurality of pixel transistors may be formed through a semiconductor process and may be located on a semiconductor substrate (SSUB in FIG. 7). For example, a plurality of pixel transistors of a data driver 700 may be formed of a complementary metal oxide semiconductor (CMOS).

Each of the plurality of pixels PX1, PX2, and PX3 may be connected to any one write scan line GWL of the plurality of write scan lines GWL, any one bias scan line GBL of the plurality of bias scan lines GBL, any one emission control line EL of the plurality of emission control lines EL, and any one data line DL of the plurality of data lines DL. Each of the plurality of pixels PX1, PX2, and PX3 may receive a data voltage of the data line DL according to a write scan signal of the write scan line GWL, and may emit light from a light-emitting element according to the data voltage.

The non-display area NDA includes a scan driver 610, a light-emitting driver 620, and a data driver 700.

The scan driver 610 includes a plurality of scan transistors, and the light-emitting driver 620 includes a plurality of light-emitting transistors. The plurality of scan transistors and the plurality of light-emitting transistors may be formed through a semiconductor process and may be formed on a semiconductor substrate (SSUB in FIG. 7). For example, the plurality of scan transistors and the plurality of light-emitting transistors may be formed of CMOS. It is illustrated in FIG. 2 that the scan driver 610 is located on the left side of the display area DAA and the light-emitting driver 620 is located on the right side of the display area DAA, but the present specification is not limited thereto. For example, the scan driver 610 and the light-emitting driver 620 may be located on both the left and right sides of the display area DAA.

The scan driver 610 may include a write scan signal output unit 611 and a bias scan signal output unit 612. Each of the write scan signal output unit 611 and the bias scan signal output unit 612 may receive a scan-timing control signal SCS from a timing control circuit 400. The write scan signal output unit 611 may generate write scan signals according to the scan-timing control signal SCS of the timing control circuit 400 and sequentially output the write scan signals to the write scan lines GWL. The bias scan signal output unit 612 may generate bias scan signals according to the scan-timing control signal SCS and sequentially output the bias scan signals to the bias scan lines GBL.

The light-emitting driver 620 may generate emission control signals according to an emission-timing control signal ECS and sequentially output the emission control signals to the emission control lines EL.

The data driver 700 may include a plurality of data transistors, and the plurality of data transistors may be formed through a semiconductor process and may be formed on a semiconductor substrate (SSUB in FIG. 7). For example, the plurality of data transistors may be formed of CMOS.

The data driver 700 may receive digital video data DATA and a data-timing control signal DCS from the timing control circuit 400. The data driver 700 converts the digital video data DATA into analog data voltages according to the data-timing control signal DCS, and outputs the converted analog data voltages to the data lines DL. In this case, the pixels PX1, PX2, and PX3 may be selected by the write scan signal of the scan driver 610, and the data voltages may be supplied to the selected pixels PX1, PX2, and PX3.

The heat dissipation layer 200 may overlap the display panel 100 in a third direction DR3, which is a thickness direction of the display panel 100. The heat dissipation layer 200 may be located on one surface of the display panel 100, for example, a rear surface of the display panel 100. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

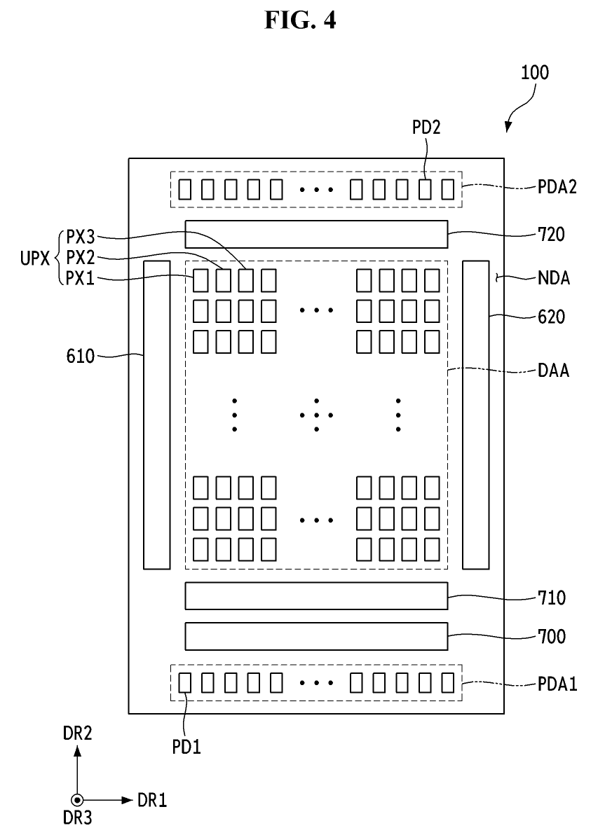

The circuit board 300 may be electrically connected to a plurality of first pads (PD1 in FIG. 4) of a first pad portion (PDA1 in FIG. 4) of the display panel 100 by using a conductive adhesive member such as an anisotropic conductive film. The circuit board 300 may be a flexible printed circuit board or flexible film made of a flexible material. It is illustrated in FIG. 1 that the circuit board 300 is unfolded, but the circuit board 300 may be bent. In this case, one end of the circuit board 300 may be located on the rear surface of the display panel 100 and/or a rear surface of the heat dissipation layer 200. The other end of the circuit board 300 may be an end opposite to the other end of the circuit board 300 connected to a plurality of first pads (PD1 in FIG. 4) of a first pad portion (PDA1 in FIG. 4) of the display panel 100 by using a conductive adhesive member.

The timing control circuit 400 may receive digital video data and timing signals from the outside. The timing control circuit 400 may generate a scan-timing control signal SCS, an emission-timing control signal ECS, and a data-timing control signal DCS for controlling the display panel 100 according to the timing signals. The timing control circuit 400 may output the scan-timing control signal SCS to the scan driver 610 and output the emission-timing control signal ECS to the light-emitting driver 620. The timing control circuit 400 may output the digital video data and the data-timing control signal DCS to the data driver 700.

The power supply circuit 500 may generate a plurality of panel driving voltages according to a power voltage from the outside. For example, the power supply circuit 500 may generate a common voltage VSS, a driving voltage VDD, an initialization voltage VINT, and a reset voltage VRES, and may supply the common voltage VSS, the driving voltage VDD, the initialization voltage VINT, and the reset voltage VRES to the display panel 100. The common voltage VSS, the driving voltage VDD, the initialization voltage VINT, and the reset voltage VRES are described later with reference to FIG. 3.

Each of the timing control circuit 400 and the power supply circuit 500 may be formed as an integrated circuit (IC) and attached to one surface of the circuit board 300. In this case, the scan-timing control signal SCS, the emission-timing control signal ECS, the digital video data DATA, and the data-timing control signal DCS of the timing control circuit 400 may be supplied to the display panel 100 through the circuit board 300. In addition, the common voltage VSS, the driving voltage VDD, the initialization voltage VINT, and the reset voltage VRES of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the light-emitting driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process and may be formed on a semiconductor substrate (SSUB in FIG. 7). For example, the plurality of timing transistors and the plurality of power transistors may be formed of CMOS. Each of the timing control circuit 400 and the power supply circuit 500 may be located between the data driver 700 and the first pad portion (PDA1 in FIG. 4).

FIG. 3 is an equivalent circuit diagram of a first pixel according to one or more embodiments.

Referring to FIG. 3, a first pixel PX1 may be connected to the write scan line GWL, the bias scan line EBL, the emission control line EL, and the data line DL. In addition, the first pixel PX1 may be connected to a common voltage line VSL to which a common voltage VSS corresponding to a low potential voltage is applied, a driving voltage line VDL to which a driving voltage VDD corresponding to a high potential voltage is applied, an initialization voltage line VIL to which an initialization voltage VINT is applied, and a reset line REL to which a reset voltage VRES is applied. In this case, the common voltage VSS may be a voltage that is less than the initialization voltage VINT. The driving voltage VDD may be a voltage greater than the initialization voltage VINT. In addition, the reset voltage VRES may be a voltage that is greater than the common voltage and that is less than the driving voltage VDD.

The first pixel PX1 may include a plurality of transistors T1 to T5, a light-emitting element LE, and a capacitor CP.

The light-emitting element LE emits light according to a driving current flowing through a channel of a first transistor T1. An amount of light emitted from the light-emitting element LE may be proportional to the driving current. The light-emitting element LE may be connected between a fifth transistor T5 and common voltage line VSL. A first electrode of the light-emitting element LE may be connected to a drain electrode of the fifth transistor T5, and a second electrode thereof may be connected to the common voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but the present specification is not limited thereto. For example, the light-emitting element LE may be an inorganic light-emitting element including a first electrode, a second electrode, and an inorganic semiconductor located between the first electrode and the second electrode. In this case, the light-emitting element LE may be a micro light-emitting diode.

The first transistor T1 may be a driving transistor that controls a source-drain current (hereinafter, referred to as “driving current”) flowing between a source electrode and a drain electrode according to a voltage applied to a gate electrode. The first transistor T1 may include a gate electrode connected to a first node N1, a source electrode connected to a second node N2, a drain electrode connected to a source electrode of a fifth transistor T5, and a body electrode connected to the driving voltage line VDL.

A second transistor T2 may be connected between the data line DL and the first node N1. The second transistor T2 may be turned on by the write scan signal of the write scan line GWL, and may electrically connect the data line DL and the first node N1. Accordingly, the data voltage from the data line DL may be applied to one electrode of the capacitor CP connected to the first node N1. The second transistor T2 may include a gate electrode connected to the write scan line GWL, a source electrode connected to the data line DL, a drain electrode connected to the first node N1, and a body electrode connected to the driving voltage line VDL.

A third transistor T3 may be connected between the driving voltage line VDL and the second node N2. The third transistor T3 may be turned on by the emission control signal EM of the emission control line EL, and may electrically connect the driving voltage line VDL and the second node N2 to each other. The third transistor T3 may include a gate electrode connected to the emission control line EL, a source electrode connected to the driving voltage line VDL, a drain electrode connected to the second node N2, and a body electrode connected to the driving voltage line VDL.

A fourth transistor T4 may be connected between the third node N3 and the initialization voltage line VIL. The fourth transistor T4 may be turned on by the bias scan signal of the bias scan line EBL, and may electrically connect the third node N3 and the initialization voltage line VIL to each other. The fourth transistor T4 may include a gate electrode connected to the bias scan line EBL, a source electrode connected to the third node N3, a drain electrode connected to the initialization voltage line VIL, and a body electrode connected to the driving voltage line VDL.

A fifth transistor T5 may be connected between the drain electrode of the first transistor T1 and the third node N3. The fifth transistor T5 may be turned on by the reset voltage VRES of the reset line REL, and may electrically connect the drain electrode of the first transistor T1 and the third node N3 to each other. The fifth transistor T5 may include a gate electrode connected to the reset line REL, a source electrode connected to the drain electrode of the first transistor T1, a drain electrode connected to the third node N3, and a body electrode connected to the driving voltage line VDL.

The capacitor CP may be connected between the first node N1 and the second node N2. The capacitor CP may include a first capacitor electrode connected to the first node N1 and a second capacitor electrode connected to the second node N2.

Each of the first transistor T1, the second transistor T2, the third transistor T3, the fourth transistor T4, and the fifth transistor T5 may be a metal-oxide-semiconductor field effect transistor (MOSFET). For example, each of the first transistor T1, the second transistor T2, the third transistor T3, the fourth transistor T4, and the fifth transistor T5 may be a P-type MOSFET.

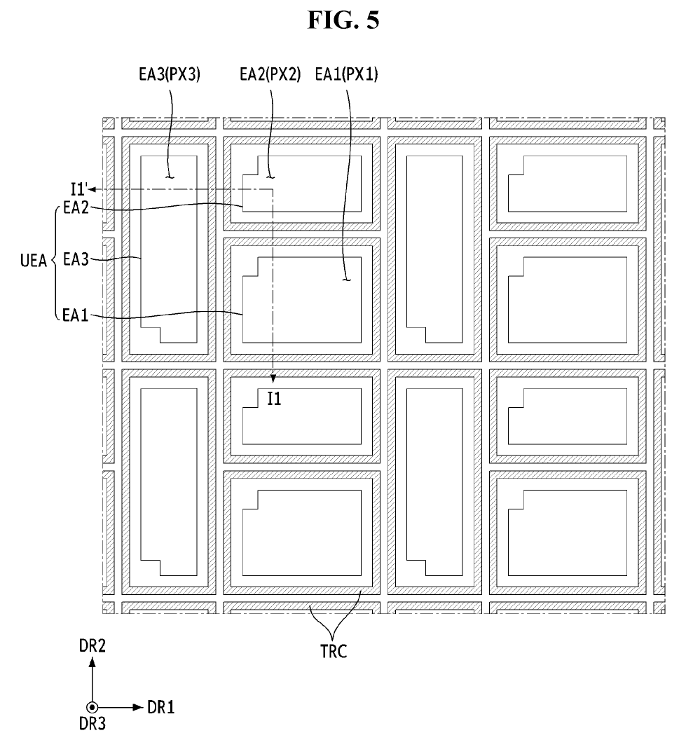

It is illustrated in FIG. 3 that the first pixel PX1 includes five transistors T1 to T5 and one capacitor CP, but the equivalent circuit diagram of the first pixel PX1 is not limited to that illustrated in FIG. 5. For example, the number of transistors and capacitors of the first pixel PX1 is not limited to that illustrated in FIG. 3.

In addition, an equivalent circuit diagram of the second pixel PX2 and an equivalent circuit diagram of the third pixel PX3 may be substantially the same as the equivalent circuit diagram of the first pixel PX1 described with reference to FIG. 3. Therefore, the descriptions of the equivalent circuit diagram of the second pixel PX2 and the equivalent circuit diagram of the third pixel PX3 are omitted in the present specification.

FIG. 4 is a layout view illustrating an example of a display panel according to one or more embodiments.

Referring to FIG. 4, the display area DAA of the display panel 100 according to one or more embodiments includes a plurality of pixels PX arranged in a matrix form. The non-display area NDA of the display panel 100 according to one or more embodiments includes a scan driver 610, a light-emitting driver 620, a data driver 700, a first distribution circuit 710, a second distribution circuit 720, a first pad portion PDA1, and a second pad portion PDA2.

The scan driver 610 may be located on a first side of the display area DAA, and the light-emitting driver 620 may be located on a second side of the display area DAA. For example, the scan driver 610 may be located on one side of the display area DAA in the first direction DR1, and the light-emitting driver 620 may be located on the other side of the display area DAA in the first direction DR1. That is, the scan driver 610 may be located on a left side of the display area DAA, and the light-emitting driver 620 may be located on a right side of the display area DAA. However, the present specification is not limited thereto, and the scan driver 610 and the light-emitting driver 620 may be located on both the first side and the second side of the display area DAA.

The first pad portion PDA1 may include a plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2.

The first pad portion PDA1 may be located on the outside of the data driver 700 in the second direction DR2. That is, the first pad portion PDA1 may be located closer to an edge of the display panel 100 than the data driver 700.

The second pad portion PDA2 may include a plurality of second pads PD2 corresponding to test pads for testing whether the display panel 100 is normally operating. The plurality of second pads PD2 may be connected to a jig or probe pin or to a test circuit board during the test process. The test circuit board may be a printed circuit board made of a rigid material or a flexible printed circuit board made of a flexible material.

The first distribution circuit 710 distributes the data voltages applied through the first pad portion PDA1 to the plurality of data lines DL. For example, the first distribution circuit 710 may distribute data voltages applied through one first pad PD1 of the first pad portion PDA1 to P (P is a positive integer greater than or equal to 2) data lines DL, thereby reducing the number of first pads PD1. The first distribution circuit 710 may be located on a third side of the display area DAA of the display panel 100. For example, the first distribution circuit 710 may be located on one side of the display area DAA in the second direction DR2. That is, the first distribution circuit 710 may be located on a lower side of the display area DAA.

The second distribution circuit 720 distributes signals applied through the second pad portion PDA2 to the scan driver 610, the light-emitting driver 620, and the data lines DL. The second pad portion PDA2 and the second distribution circuit 720 may be components for testing the operation of each pixel PX of the display area DAA. The second distribution circuit 720 may be located on a fourth side of the display area DAA of the display panel 100. For example, the second distribution circuit 720 may be located on the other side of the display area DAA in the second direction DR2. That is, the second distribution circuit 720 may be located on an upper side of the display area DAA.

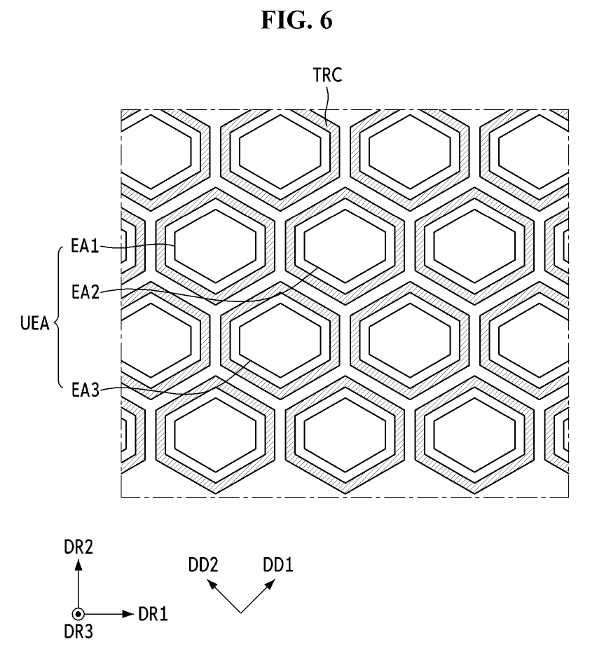

FIGS. 5 and 6 are layout views illustrating examples of a display area of FIG. 4.

Referring to FIGS. 5 and 6, each of the plurality of unit pixels UPX may include a first light-emitting area EA1, which is a light-emitting area of the first pixel PX1, a second light-emitting area EA2, which is a light-emitting area of the second pixel PX2, and a third light-emitting area EA3, which is a light-emitting area of the third pixel PX3. In other words, because the unit pixel UPX may include a unit light-emitting area UEA, the unit light-emitting area UEA may include the first light-emitting area EA1, the second light-emitting area EA2, and the third light-emitting area EA3 described above.

Each of the first light-emitting area EA1, the second light-emitting area EA2, and the third light-emitting area EA3 may have a polygonal, circular, elliptical, or irregular planar shape.

A maximum length of the first light-emitting area EA1 in the first direction DR1 may be less than a maximum length of the second light-emitting area EA2 in the first direction DR1 and a maximum length of the third light-emitting area EA3 in the first direction DR1. The maximum length of the second light-emitting area EA2 in the first direction DR1 and the maximum length of the third light-emitting area EA3 in the first direction DR1 may be substantially the same.

A maximum length of the first light-emitting area EA1 in the second direction DR2 may be longer than a maximum length of the second light-emitting area EA2 in the second direction DR2 and a maximum length of the third light-emitting area EA3 in the second direction DR2. The maximum length of the second light-emitting area EA2 in the second direction DR2 may be longer than the maximum length of the third light-emitting area EA3 in the second direction DR2. The maximum length of the first light-emitting area EA1 in the second direction DR2 may be less than the maximum length of the second light-emitting area EA2 in the second direction DR2.

The first light-emitting area EA1, the second light-emitting area EA2, and the third light-emitting area EA3 may have a hexagonal planar shape including six straight lines as illustrated in FIGS. 5 and 6, but the present specification is not limited thereto. The first light-emitting area EA1, the second light-emitting area EA2, and the third light-emitting area EA3 have a planar shape other than the hexagon, such as a polygon, circle, ellipse, or irregular shape.

As illustrated in FIG. 5, in each of the plurality of pixels PX1, PX2, and PX3, the first light-emitting area EA1 and the second light-emitting area EA2 may be adjacent to each other in the second direction DR2. In addition, the first light-emitting area EA1 and the third light-emitting area EA3 may be adjacent to each other in the first direction DR1. In addition, the second light-emitting area EA2 and the third light- emitting area EA3 may be adjacent to each other in the first direction DR1. An area of the first light-emitting area EA1, an area of the second light-emitting area EA2, and an area of the third light-emitting area EA3 may be different.

Alternatively, as illustrated in FIG. 6, the first light-emitting area EA1 and the second light-emitting area EA2 are adjacent to each other in the first direction DR1, but the second light-emitting area EA2 and the third light-emitting area EA3 may be adjacent to each other in a first diagonal direction DD1, and the first light-emitting area EA1 and the third light-emitting area EA3 may be adjacent to each other in a second diagonal direction DD2. The first diagonal direction DD1, which is a direction between the first direction DR1 and the second direction DR2, may indicate a direction inclined by about 45 degrees compared to the first direction DR1 and the second direction DR2, and the second diagonal direction DD2 may be a direction substantially perpendicular to the first diagonal direction DD1.

The first light-emitting area EA1 emits light of a first color, the second light-emitting area EA2 emits light of a second color, and the third light-emitting area EA3 emits light of a third color. Here, the light of the first color may be light in a blue wavelength band, the light of the second color may be light in a green wavelength band, and the light of the third color may be light in a red wavelength band. For example, the blue wavelength band may indicate that a main peak wavelength of light is included in a wavelength band of approximately 370 nm to approximately 460 nm, the green wavelength band may indicate that a main peak wavelength of light is included in a wavelength band of approximately 480 nm to approximately 560 nm, and the red wavelength band may indicate that a main peak wavelength of light is included in a wavelength band of approximately 600 nm to approximately 750 nm.

In addition, the arrangement of the light-emitting areas EA1, EA2, and EA3 of the plurality of pixels PX1, PX2, and PX3 is not limited to that illustrated in FIGS. 5 and 6. For example, the light-emitting areas EA1, EA2, and EA3 of the plurality of pixels PX1, PX2, and PX3 may be located in a stripe structure in which the light-emitting areas are arranged in the first direction DR1, a PenTile® structure in which the light-emitting areas have a diamond arrangement (PenTile® being a registered trademark of Samsung Display Co., Ltd., Republic of Korea), or a hexagonal structure in which light-emitting areas having a hexagonal planar shape are arranged.

FIG. 7 is a cross-sectional view illustrating an example of the display panel taken along the line I1-I1’ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes a semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to fifth transistors T1 to T5 described with reference to FIG. 4.

The semiconductor substrate SSUB may be a silicon substrate, a germanium substrate, or a silicon-germanium substrate. The semiconductor substrate SSUB may be a substrate doped with first-type impurities. A plurality of well areas WA may be located in an upper surface of the semiconductor substrate SSUB. The plurality of well areas WA may be areas doped with second-type impurities. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

Each of the plurality of well areas WA includes a source area SA corresponding to a source electrode of the pixel transistor PTR, a drain area DA corresponding to a drain electrode thereof, and a channel area CH located between the source area SA and the drain area DA.

A lower insulating layer BINS may be located between the gate electrode GE and the well area WA. A side insulating layer SINS may be located on a side surface of the gate electrode GE. The side insulating layer SINS may be located on the lower insulating layer BINS.

Each of the source area SA and the drain area DA may be an area doped with first-type impurities. The gate electrode GE of the pixel transistor PTR may overlap the well area WA in the third direction DR3. The channel area CH may overlap the gate electrode GE in the third direction DR3. The source area SA may be located on one side of the gate electrode GE, and the drain area DA may be located on the other side of the gate electrode GE.

Each of the plurality of well areas WA further includes a first low-concentration impurity area LDD1 located between the channel area CH and the source area SA and a second low-concentration impurity area LDD2 located between the channel area CH and the drain area DA. The first low-concentration impurity area LDD1 may be an area having an impurity concentration lower than that of the source area SA due to the lower insulating layer BINS. The second low-concentration impurity area LDD2 may be an area having an impurity concentration lower than that of the drain area DA due to the lower insulating layer BINS. A distance between the source area SA and the drain area DA may be increased due to the first low-concentration impurity area LDD1 and the second low-concentration impurity area LDD2. Therefore, because a length of the channel area CH of each of the pixel transistors PTR may increase, punch-through and hot carrier phenomena caused by a short channel may be reduced or prevented.

A first semiconductor insulating layer SINS1 may be located on the semiconductor substrate SSUB (as used herein, “located on” may mean “above”). The first semiconductor insulating film SINS1 may be formed as a silicon nitride carbon (SiCN) or silicon oxide (SiOx)-based inorganic film, but the present specification is not limited thereto.

A second semiconductor insulating layer SINS2 may be located on the first semiconductor insulating layer SINS1. The second semiconductor insulating film SINS2 may be formed as a silicon oxide (SiOx)-based inorganic film, but the present specification is not limited thereto.

The plurality of contact terminals CTE may be located on the second semiconductor insulating layer SINS2. Each of the plurality of contact terminals CTE may be connected to any one of the gate electrode GE, the source area SA, or the drain area DA of each of the pixel transistors PTR through a hole penetrating through the first semiconductor insulating layer SINS1 and the second semiconductor insulating layer SINS2. The plurality of contact terminals CTE may include any one of copper (Cu), aluminum (Al), tungsten (W), molybdenum (Mo), chromium (Cr), gold (Au), titanium (Ti), nickel (Ni), or neodymium (Nd), or an alloy including any one thereof.

A third semiconductor insulating layer SINS3 may be located on a side surface of each of the plurality of contact terminals CTE. An upper surface of each of the plurality of contact terminals CTE may be exposed without being covered by the third semiconductor insulating layer SINS3. The third semiconductor insulating layer SINS3 may be formed as a silicon oxide (SiOx)-based inorganic film, but the present specification is not limited thereto.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that is not typically bent, and the polymer resin substrate may be a flexible substrate that may be bent or curved.

The light-emitting element backplane EBP includes a plurality of conductive layers ML1 to ML8, a plurality of via electrodes VA1 to VA8, and a plurality of insulating layers INS1 to INS9. In addition, the light-emitting element backplane EBP includes a plurality of insulating layers INS1 to INS11 located between first to eighth conductive layers ML1 to ML8.

The first to eighth conductive layers ML1 to ML8 serve to implement the circuit of the first pixel PX1 illustrated in FIG. 3 by connecting the plurality of contact terminals CTE exposed from the semiconductor backplane SBP. For example, only the first to fifth transistors T1 to T5 are formed in the semiconductor backplane SBP, and the connection of the first to fifth transistors T1 to T5 and the capacitor CP is formed through the first to eighth conductive layers ML1 to ML8. In addition, the source area corresponding to the source electrode of the fourth transistor T4, the drain area corresponding to the drain electrode of the fifth transistor T5, and the first electrode of the light-emitting element LE are also connected through the first to eighth conductive layers ML1 to ML8.

A first insulating layer INS1 may be located on the semiconductor backplane SBP. Each first via electrode VA1 may penetrate through the first insulating layer INS1 and be connected to the contact terminal CTE exposed from the semiconductor backplane SBP. Each of the first conductive layers ML1 may be located on the first insulating layer INS1 and may be connected to the first via electrode VA1.

A second insulating layer INS2 may be located on the first insulating layer INS1 and the first conductive layers ML1. Each second via electrode VA2 may be connected to the first conductive layer ML1 exposed by penetrating through the second insulating layer INS2. Each of the second conductive layers ML2 may be located on the second insulating layer INS2 and may be connected to the second via electrode VA2.

A third insulating layer INS3 may be located on the second insulating layer INS2 and the second conductive layers ML2. Each third via electrode VA3 may be connected to the second conductive layer ML2 exposed by penetrating through the third insulating layer INS3. Each of the third conductive layers ML3 may be located on the third insulating layer INS3 and may be connected to the third via electrode VA3.

A fourth insulating layer INS4 may be located on the third insulating layer INS3 and the third conductive layers ML3. Each fourth via electrode VA4 may be connected to the third conductive layer ML3 exposed by penetrating through the fourth insulating layer INS4. Each of the fourth conductive layers ML4 may be located on the fourth insulating layer INS4 and may be connected to the fourth via electrode VA4.

A fifth insulating layer INS5 may be located on the fourth insulating layer INS4 and the fourth conductive layers ML4. Each fifth via electrode VA5 may be connected to the fourth conductive layer ML4 exposed by penetrating through the fifth insulating layer INS5. Each of the fifth conductive layers ML5 may be located on the fifth insulating layer INS5 and may be connected to the fifth via electrode VA5.

A sixth insulating layer INS6 may be located on the fifth insulating layer INS5 and the fifth conductive layers ML5. Each sixth via electrode VA6 may be connected to the fifth conductive layer ML5 exposed by penetrating through the sixth insulating layer INS6. Each of the sixth conductive layers ML6 may be located on the sixth insulating layer INS6 and may be connected to the sixth via electrode VA6.

A seventh insulating layer INS7 may be located on the sixth insulating layer INS6 and the sixth conductive layers ML6. Each seventh via electrode VA7 may be connected to the sixth conductive layer ML6 exposed by penetrating through the seventh insulating layer INS7. Each of the seventh conductive layers ML7 may be located on the seventh insulating layer INS7 and may be connected to the seventh via electrode VA7.

An eighth insulating layer INS8 may be located on the seventh insulating layer INS7 and the seventh conductive layers ML7. Each eighth via electrode VA8 may be connected to the seventh conductive layer ML7 exposed by penetrating through the eighth insulating layer INS8. Each of the eighth conductive layers ML8 may be located on the eighth insulating layer INS8 and may be connected to the eighth via electrode VA8.

The first to eighth conductive layers ML1 to ML8 and the first to eighth via electrodes VA1 to VA8 may include substantially the same material. The first to eighth conductive layers ML1 to ML8 and the first to eighth via electrodes VA1 to VA8 may include any one of copper (Cu), aluminum (Al), tungsten (W), molybdenum (Mo), chromium (Cr), gold (Au), titanium (Ti), nickel (Ni), or neodymium (Nd), or an alloy including any one thereof. The first to eighth via electrodes VA1 to VA8 may include substantially the same material. The first to eighth insulating layers INS1 to INS8 may include a silicon oxide (SiOₓ)-based inorganic film, but the present specification is not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via electrode VA1, a thickness of the second via electrode VA2, a thickness of the third via electrode VA3, a thickness of the fourth via electrode VA4, a thickness of the fifth via electrode VA5, and a thickness of the sixth via electrode VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1440 Å, and each of the thickness of the first via electrode VA1, the thickness of the second via electrode VA2, the thickness of the third via electrode VA3, the thickness of the fourth via electrode VA4, the thickness of the fifth via electrode VA5, and the thickness of the sixth via electrode VA6 may be approximately 1150 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the thickness of the eighth conductive layer ML8 may be greater than each of a thickness of the seventh via electrode VA7 and a thickness of the eighth via electrode VA8. Each of the thickness of the seventh via electrode VA7 and the thickness of the eighth via electrode VA8 may be greater than each of the thickness of the first via electrode VA1, the thickness of the second via electrode VA2, the thickness of the third via electrode VA3, the thickness of the fourth via electrode VA4, the thickness of the fifth via electrode VA5, and the thickness of the sixth via electrode VA6. The thickness of the seventh conductive layer ML7 and the thickness of the eighth conductive layer ML8 may be substantially the same. For example, each of the thickness of the seventh conductive layer ML7 and the thickness of the eighth conductive layer ML8 may be approximately 9000 Å. Each of the thicknesses of the seventh via electrode VA7 and the eighth via electrode VA8 may be approximately 6000 Å.

A ninth insulating layer INS9 may be located on the eighth insulating layer INS8 and the eighth conductive layer ML8. The ninth insulating layer INS9 may be formed as a silicon oxide (SiOx)-based inorganic film, but the present specification is not limited thereto.

Each ninth via electrode VA9 may be connected to the eighth conductive layer ML8 exposed by penetrating through the ninth insulating layer INS9. The ninth via electrodes VA9 may include any one of copper (Cu), aluminum (Al), tungsten (W), molybdenum (Mo), chromium (Cr), gold (Au), titanium (Ti), nickel (Ni), or neodymium (Nd), or an alloy including any one thereof. A thickness of the ninth via electrode VA9 may be approximately 16500 Å.

The display element layer EML may be located on the light-emitting element backplane EBP. The display element layer EML may include light-emitting elements each including a reflective electrode layer RL, tens and eleventh insulating layers INS10 and INS11, a tenth via electrode VA10, a first electrode AND, a light-emitting stack ES, and a second electrode CAT, a pixel-defining layer PDL, and a plurality of trenches TRC.

The reflective electrode layer RL may be located on the ninth insulating layer INS9. The reflective electrode layer RL may include one or more reflective electrodes RL1, RL2, RL3, and RL4. For example, the reflective electrode layer RL may include first to fourth reflective electrodes RL1, RL2, RL3, and RL4 as illustrated in FIG. 7.

Each first reflective electrode RL1 may be located on the ninth insulating layer INS9 and may be connected to the ninth via electrode VA9. The first reflective electrodes RL1 may include any one of copper (Cu), aluminum (Al), tungsten (W), molybdenum (Mo), chromium (Cr), gold (Au), titanium (Ti), nickel (Ni), or neodymium (Nd), or an alloy including any one thereof. For example, the first reflective electrodes RL1 may include titanium nitride (TiN).

Each second reflective electrode RL2 may be located on a respective first reflective electrode RL1. The second reflective electrodes RL2 may include any one of copper (Cu), aluminum (Al), tungsten (W), molybdenum (Mo), chromium (Cr), gold (Au), titanium (Ti), nickel (Ni), or neodymium (Nd), or an alloy including any one thereof. For example, the second reflective electrode RL2 may include aluminum (Al).

Each third reflective electrode RL3 may be located on a respective second reflective electrode RL2. The third reflective electrodes RL3 may include any one of copper (Cu), aluminum (Al), tungsten (W), molybdenum (Mo), chromium (Cr), gold (Au), titanium (Ti), nickel (Ni), or neodymium (Nd), or an alloy including any one thereof. For example, the third reflective electrodes RL3 may include titanium nitride (TiN).

Each fourth reflective electrode RL4 may be located on a respective third reflective electrode RL3. The fourth reflective electrodes RL4 may include any one of copper (Cu), aluminum (Al), tungsten (W), molybdenum (Mo), chromium (Cr), gold (Au), titanium (Ti), nickel (Ni), or neodymium (Nd), or an alloy including any one thereof. For example, the fourth reflective electrode RL4 may include titanium (Ti).

Because the second reflective electrode RL2 may be an electrode that substantially reflects light from the light-emitting elements, a thickness of the second reflective electrode RL2 may be greater than a thickness of the first reflective electrode RL1, a thickness of the third reflective electrode RL3, and a thickness of the fourth reflective electrode RL4. For example, the thickness of the first reflective electrode RL1, the thickness of the third reflective electrode RL3, and the thickness of fourth reflective electrode RL4 are approximately 100 Å, and the thickness of the second reflective electrode RL2 may be approximately 850 Å.

The tenth insulating layer INS10 may be located on the ninth insulating layer INS9. The tenth insulating layer INS10 may be located between the reflective electrode layers RL adjacent to each other in the horizontal direction. The tenth insulating layer INS10 may be located on the reflective electrode layer RL in the third pixel PX3. The tenth insulating layer INS10 may be formed as a silicon oxide (SiOx)-based inorganic film, but the present specification is not limited thereto.

The eleventh insulating layer 0 may be located on the tenth insulating layer INS10 and the reflective electrode layer RL. The eleventh insulating layer INS11 may be formed as a silicon oxide (SiOx)-based inorganic film, but the present specification is not limited thereto. The tenth insulating layer INS10 and the eleventh insulating layer INS11 may be optical auxiliary layers through which light reflected by the reflective electrode layer RL among the light emitted from the light-emitting elements LE passes.

To match a resonance distance of light emitted from light-emitting elements LE in at least one pixel of the first pixel PX1, the second pixel PX2, or the third pixel PX3, the eleventh insulating layer INS11 may not be located under, or may be omitted from under, the first electrode AND of the first pixel PX1, in one or more embodiments. In one or more embodiments, the first electrode AND of the first pixel PX1 may be directly located on the reflective electrode layer RL.

The eleventh insulating layer INS11 may be located under the first electrode AND of the second pixel PX2. The eleventh insulating layer INS11, which is thicker than the eleventh insulating layer INS11 located under the second pixel PX2, may be located under the first electrode AND of the third pixel PX3. In one or more embodiments, the eleventh insulating layer INS11, which is thinner than the eleventh insulating layer INS11 located under the second pixel PX2, may be located under the first electrode AND of the first pixel PX1.

In summary, a distance between the first electrode AND and the reflective electrode layer RL may be different in each of the first pixel PX1, the second pixel PX2, and the third pixel PX3. That is, to adjust a distance from the reflective electrode layer RL to the second electrode CAT according to a main wavelength of light emitted from each of the first pixel PX1, the second pixel PX2, and the third pixel PX3, the presence or absence of the eleventh insulating layer INS11 in each of the first pixel PX1, the second pixel PX2, and the third pixel PX3 may be set. For example, it is illustrated in FIG. 6 that a distance between the first electrode AND and the reflective electrode layer RL in the first pixel PX1 is greater than a distance between the first electrode AND and the reflective electrode layer RL in the second pixel PX2 and a distance between the first electrode AND and the reflective electrode layer RL in the third pixel PX3, and the distance between the first electrode AND and the reflective electrode layer RL in the second pixel PX2 is greater than a distance between the first electrode AND and the reflective electrode layer RL in the first pixel PX1, but the present specification is not limited thereto.

Each of the tenth via electrodes VA10 may be connected to the fourth reflective electrode RL4 exposed by penetrating through the eleventh insulating layer INS11 in the second pixel PX2 and the third pixel PX3 (e.g., and also in the first pixel PX1, in one or more embodiments). The eleventh via electrodes VA10 may include any one of copper (Cu), aluminum (Al), tungsten (W), molybdenum (Mo), chromium (Cr), gold (Au), titanium (Ti), nickel (Ni), or neodymium (Nd), or an alloy including any one thereof. The thickness of the tenth via electrode VA10 in the second pixel PX2 may be less than the thickness of the tenth via electrode VA10 in the third pixel PX3.

The first electrode AND of each of the light-emitting elements LE may be located on the eleventh insulating layer INS11, and may be connected to the tenth via electrode VA10. The first electrode AND of each of the light-emitting elements LE may be connected to the drain area DA or the source area SA of the pixel transistor PTR through the tenth via VA10, the first to fourth reflective electrodes RL1 to RL4, the first to ninth via electrodes VA1 to VA9, the first to eighth conductive layers ML1 to ML8, and the contact terminal CTE. The first electrode AND of each of the light-emitting elements LE may include any one of copper (Cu), aluminum (Al), tungsten (W), molybdenum (Mo), chromium (Cr), gold (Au), titanium (Ti), nickel (Ni), or neodymium (Nd), or an alloy including any one thereof. For example, the first electrode AND of each of the light-emitting elements LE may include titanium nitride (TiN).

The pixel-defining layer PDL may be located on a partial area of the first electrode AND of each of the light-emitting elements LE. The pixel-defining layer PDL may cover an edge of the first electrode AND of each of the light-emitting elements LE. The pixel-defining layer PDL serves to partition the first light-emitting areas EA1, the second light-emitting areas EA2, and the third light-emitting areas EA3.

The first light-emitting area EA1 may be defined as an area in which the first electrode AND, the light-emitting stack ES, and the second electrode CAT are sequentially stacked in the first pixel PX1 to emit light. The second light-emitting area EA2 may be defined as an area in which the first electrode AND, the light-emitting stack ES, and the second electrode CAT are sequentially stacked in the second pixel PX2 to emit light. The third light-emitting area EA3 may be defined as an area in which the first electrode AND, the light-emitting stack ES, and the second electrode CAT are sequentially stacked in the third pixel PX3 to emit light.

The pixel-defining layer PDL may include first to third pixel-defining layers PDL1, PDL2, and PDL3. The first pixel-defining layer PDL1 may be located on the edge of the first electrode AND of each of the light-emitting elements LE, the second pixel-defining layer PDL2 may be located on the first pixel-defining layer PDL1, and the third pixel-defining layer PDL3 may be located on the second pixel-defining layer PDL2. The first pixel-defining layer PDL1, the second pixel-defining layer PDL2, and the third pixel-defining layer PDL3 may be formed as a silicon oxide (SiOx)-based inorganic film, but the present specification is not limited thereto. Each of a thickness of the first pixel-defining layer PDL1, a thickness of the second pixel-defining layer PDL2, and a thickness of the third pixel-defining layer PDL3 may be approximately 500 Å.

When the first pixel-defining layer PDL1, the second pixel-defining layer PDL2, and the third pixel-defining layer PDL3 are formed as a single pixel-defining layer, a first encapsulation inorganic layer TFE1 may be disconnected due to step coverage because a height of the single pixel-defining layer increases. The step coverage refers to a ratio of the extent to which a thin film is applied to an inclined portion relative to the extent to which a thin film is applied to a flat portion. As the step coverage is low, the possibility of the thin film disconnected at the inclined portion may increase.

Therefore, to reduce or prevent the likelihood of the first encapsulation inorganic layer TFE1 being disconnected due to the step coverage, the first pixel-defining layer PDL1, the second pixel-defining layer PDL2, and the third pixel-defining layer PDL3 may have a cross-sectional structure with a step difference of a step shape. For example, a width of the first pixel-defining layer PDL1 may be greater than a width of the second pixel-defining layer PDL2 and a width of the third pixel-defining layer PDL3, and the width of the second pixel-defining layer PDL2 may be greater than the width of third pixel-defining layer PDL3. The width of the first pixel-defining layer PDL1 refers to a horizontal length of the first pixel-defining layer PDL1 defined by the first direction DR1 and the second direction DR2.

Each of the plurality of trenches TRC may penetrate through the first pixel-defining layer PDL1, the second pixel-defining layer PDL2, and the third pixel-defining layer PDL3. In addition, each of the plurality of trenches TRC may penetrate through the eleventh insulating layer INS11. In each of the plurality of trenches TRC, a portion of the tenth insulating layer INS10 may have a dug shape.

At least one trench TRC may be located between the pixels PX1, PX2, and PX3 adjacent to each other. It is illustrated in FIG. 6 that two trenches TRC are located between the pixels PX1, PX2, and PX3 adjacent to each other, but the present specification is not limited thereto.

The light-emitting stack ES may include a plurality of stack layers. It is illustrated in FIG. 6 that the light-emitting stack ES has a three-tandem structure including a first stack layer IL1, a second stack layer IL2, and a third stack layer IL3, but the present specification is not limited thereto. For example, the light-emitting stack ES may have a two-tandem structure including two intermediate layers.

In the three-tandem structure, the light-emitting stack ES may have a tandem structure including a plurality of stack layers IL1, IL2, and IL3 that emit different lights. For example, the light-emitting stack ES may include a first light-emitting stack IL1 that emits light of a first color, a second light-emitting stack IL2 that emits light of a third color, and a third light-emitting stack IL3 that emits light of a second color. The first stack layer IL1, the second stack layer IL2, and the third stack layer IL3 may be sequentially stacked.

The first stack layer IL1 may have a structure in which a first hole-transporting layer, a first organic light-emitting layer that emits light of a first color, and a first electron-transporting layer are sequentially stacked. The second stack layer IL2 may have a structure in which a second hole-transporting layer, a second organic light-emitting layer that emits light of a second color, and a second electron-transporting layer are sequentially stacked. The third stack layer IL3 may have a structure in which a third hole-transporting layer, a third organic light-emitting layer that emits light of a third color, and a third electron-transporting layer are sequentially stacked.

A first charge generation layer for supplying charges to the second stack layer IL2 and for supplying electrons to the first stack layer IL1 may be located between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metallic material.

A second charge generation layer for supplying charges to the third stack layer IL3 and for supplying electrons to the second stack layer IL2 may be located between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be located on the first electrodes AND and the pixel-defining layer PDL, and may be located on a bottom surface of the trench TRC in each of the trenches TRC. Due to the trench TRC, the first stack layer IL1 may be disconnected between the pixels PX1, PX2, and PX3 adjacent to each other. The second stack layer IL2 may be located on the first stack layer IL1. Due to the trench TRC, the second stack layer IL2 may be disconnected between the pixels PX1, PX2, and PX3 adjacent to each other. A cavity ESS or an empty space may be located between the first stack layer IL1 and the second stack layer IL2. The third stack layer IL3 may be located on the second stack layer IL2. The third stack layer IL3 may not be disconnected by the trench TRC, and may cover the second stack layer IL2 in each of the trenches TRC. That is, in the three-tandem structure, each of the plurality of trenches TRC may be a structure for disconnecting the first and second stack layers IL1 and IL2, the first charge generation layer, and the second charge generation layer of the display element layer EML between the pixels PX1, PX2, and PX3 adjacent to each other. In addition, in the two-tandem structure, each of the plurality of trenches TRC may be a structure for disconnecting the charge generation layer located between a lower intermediate layer and an upper intermediate layer and the lower intermediate layer.

To stably disconnect the first and second stack layers IL1 and IL2 of the display element layer EML between the pixels PX1, PX2, and PX3 adjacent to each other, a height of each of the plurality of trenches TRC may be greater than a height of the pixel-defining layer PDL. The height of each of the plurality of trenches TRC indicates a length of each of the plurality of trenches TRC in the third direction DR3. The height of the pixel-defining layer PDL indicates a length of the pixel-defining layer PDL in the third direction DR3. To disconnect the first to third stack layers IL1, IL2, and IL3 of the display element layer EML between the pixels PX1, PX2, and PX3 adjacent to each other, other structures may be present instead of the trench TRC. For example, instead of the trench TRC, a partition wall having a reverse tapered shape may be located on the pixel-defining layer PDL.

The number of stack layers IL1, IL2, and IL3 that emit different lights is not limited to that illustrated in FIG. 6. For example, the light-emitting stack ES may include two intermediate layers. In this case, one of the two intermediate layers may be substantially the same as the first stack layer IL1, and the other thereof may include a second hole-transporting layer, a second organic light-emitting layer, a third organic light-emitting layer, and a second electron-transporting layer. In this case, a charge generation layer for supplying electrons to one intermediate layer, and for supplying charges to the other intermediate layer, may be located between the two intermediate layers.

In addition, it is illustrated in FIG. 6 that the first to third stack layers IL1, IL2, and IL3 are all located in the first light-emitting area EA1, the second light-emitting area EA2, and the third light-emitting area EA3, but the present specification is not limited thereto. For example, the first stack layer IL1 may be located in the first light-emitting area EA1 and may not be located in the second light-emitting area EA2 and the third light-emitting area EA3 . In addition, the second stack layer IL2 may be located in the second light-emitting area EA2, and may not be located in, or may be omitted from, the first light-emitting area EA1 and the third light-emitting area EA3. In addition, the third stack layer IL3 may be located in the third light-emitting area EA3, and may not be located in, or may be omitted from, the first light-emitting area EA1 and the second light-emitting area EA2. In this case, first to third color filters CF1, CF2, and CF3 of the optical layer OPL may be omitted.

The second electrode CAT may be located on the third stack layer IL3. The second electrode CAT may be located on the third stack layer IL3 in each of the plurality of trenches TRC. The second electrode CAT may include a transparent conductive material (TCO), such as ITO or IZO capable of transmitting light, or a semi-transmissive conductive material, such as magnesium (Mg), silver (Ag), or an alloy of magnesium (Mg) and silver (Ag). When the second electrode CAT includes a semi-transmissive conductive material, light emission efficiency may be increased in each of the first to third pixels PX1, PX2, and PX3 by micro cavities.

The encapsulation layer TFE may be located on the display element layer EML. The encapsulation layer TFE may include one or more inorganic layers TFE1 and TFE2 to reduce or prevent oxygen or moisture from permeating into the display element layer EML. For example, the encapsulation layer TFE may include a first encapsulation inorganic layer TFE1 and a second encapsulation inorganic layer TFE2.

The first encapsulation inorganic layer TFE1 may be located on the second electrode CAT. The first encapsulation inorganic layer TFE1 may be formed as a multi-film in which one or more inorganic films of silicon nitride (SiNₓ), silicon oxynitride (SiON), and silicon oxide (SiOₓ) are alternately stacked. The first encapsulation inorganic layer TFE1 may be formed by a chemical evaporation deposition (CVD) process.

The second encapsulation inorganic layer TFE2 may be located on the first encapsulation inorganic layer TFE1. The second encapsulation inorganic layer TFE2 may be formed as a titanium oxide (TiOx) or aluminum oxide layer (AlOx), but the present specification is not limited thereto. The second encapsulation inorganic layer TFE2 may be formed by an atomic layer deposition (ALD) process. A thickness of the second encapsulation inorganic layer TFE2 may be less than a thickness of the first encapsulation inorganic layer TFE1.

The organic layer APL may be a layer for increasing an interfacial adhesion between the encapsulation layer TFE and the optical layer OPL. The organic layer APL may be an organic film made of an acryl resin, an epoxy resin, a phenolic resin, a polyamide resin, a polyimide resin, or the like.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be located on an adhesive layer ADL.

The first color filter CF1 may overlap the first light-emitting area EA1 of the first pixel PX1. The first color filter CF1 may transmit light of a first color, that is, light in a blue wavelength band. The red wavelength band may be approximately 370 nm to approximately 460 nm. Therefore, the first color filter CF1 may transmit light of a first color among light emitted from the first light-emitting area EA1.

The second color filter CF2 may overlap the second light-emitting area EA2 of the second pixel PX2. The second color filter CF2 may transmit light of a second color, that is, light in a green wavelength band. The green wavelength band may be approximately 480 nm to approximately 560 nm. Therefore, the second color filter CF2 may transmit light of a second color among light emitted from the second light-emitting area EA2.

The third color filter CF3 may overlap the third light-emitting area EA3 of the third pixel PX3. The third color filter CF3 may transmit light of a third color, that is, light in a red wavelength band. The red wavelength band may be approximately 600 nm to approximately 750 nm. Therefore, the third color filter CF3 may transmit light of a third color among light emitted from the third light-emitting area EA3.

Each of the plurality of lenses LNS may be located on each of the first color filter CF1, the second color filter CF2, and the third color filter CF3. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a refractive index so that light travels in the third direction DR3 at an interface between the plurality of lenses LNS and the filling layer FIL. In addition, the filling layer FIL may be a planarization layer. The filling layer FIL may be an organic film made of an acryl resin, an epoxy resin, a phenolic resin, a polyamide resin, a polyimide resin, or the like.

The cover layer CVL may be located on the filling layer FIL. The cover layer CVL may be a glass substrate or a polymer resin, such as resin. When the cover layer CVL is a glass substrate, the cover layer CVL may be attached onto the filling layer FIL. In this case, the filling layer FIL may serve to attach the cover layer CVL. When the cover layer CVL is a glass substrate, the cover layer CVL may serve as an encapsulation substrate. When the cover layer CVL is a polymer resin, such as resin, the cover layer CVL may be directly applied onto the filling layer FIL.

The polarizing plate POL may be located on one surface of the cover layer CVL. The polarizing plate POL may be a structure for reducing or preventing deterioration in visibility due to reflection of external light. The polarizing plate POL may include a linear polarizing plate and a phase retardation film. For example, the phase retardation film may be a λ/4 (quarter-wave) plate, but the present specification is not limited thereto. However, when visibility due to the reflection of external light is sufficiently improved by the first to third color filters CF1, CF2, and CF3, the polarizing plate POL may also be omitted.

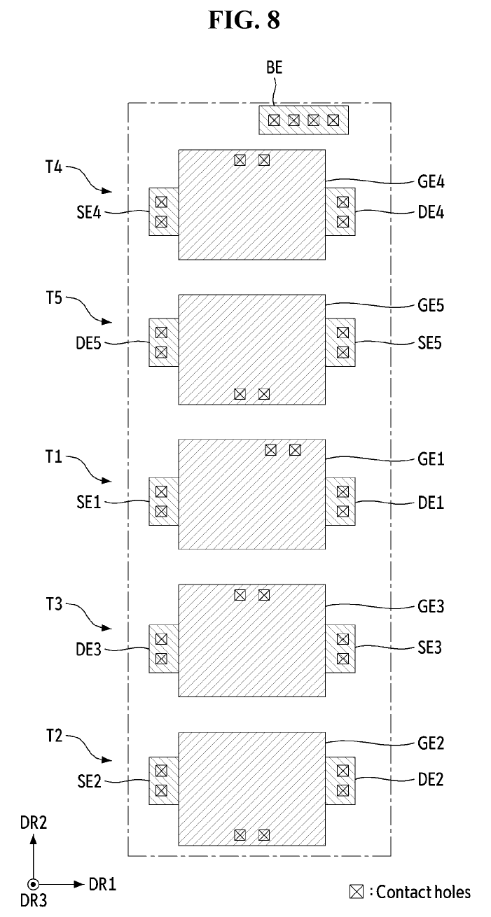

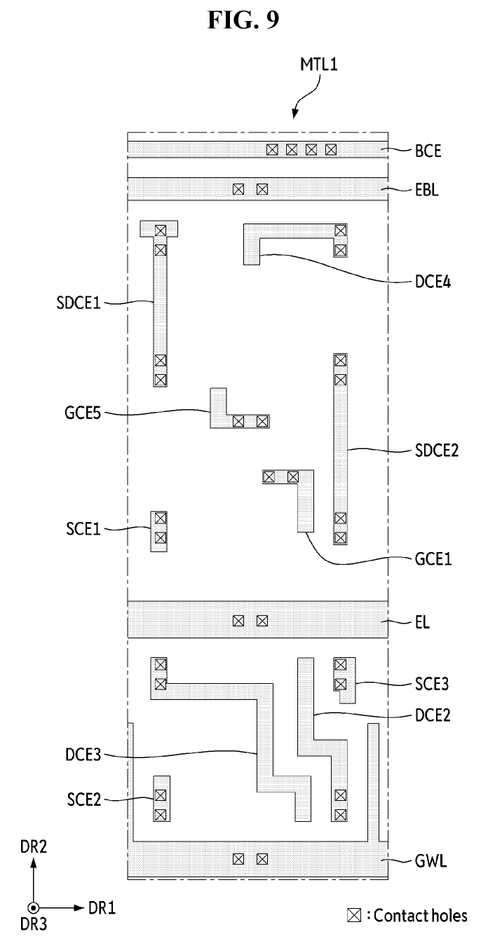

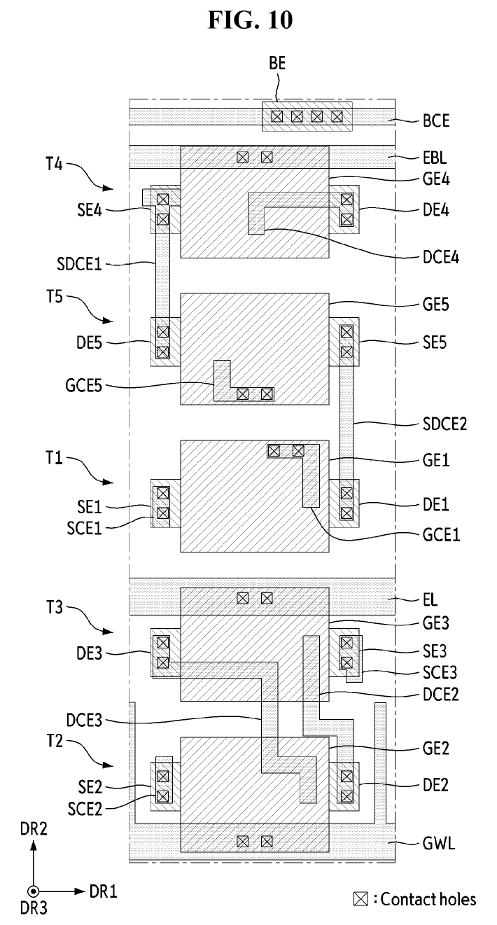

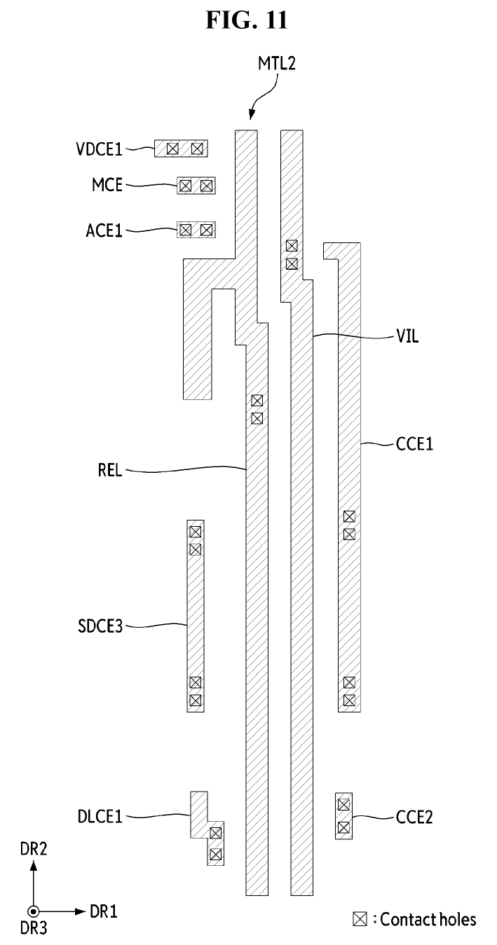

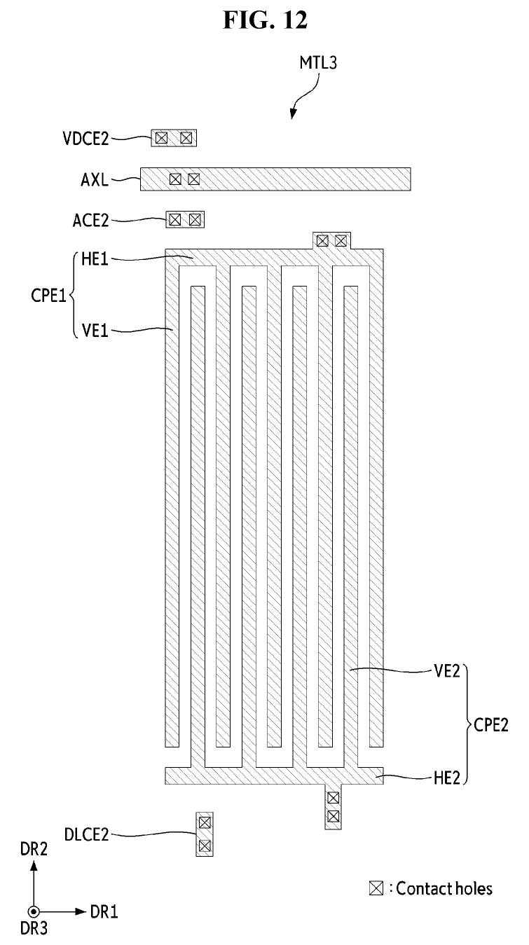

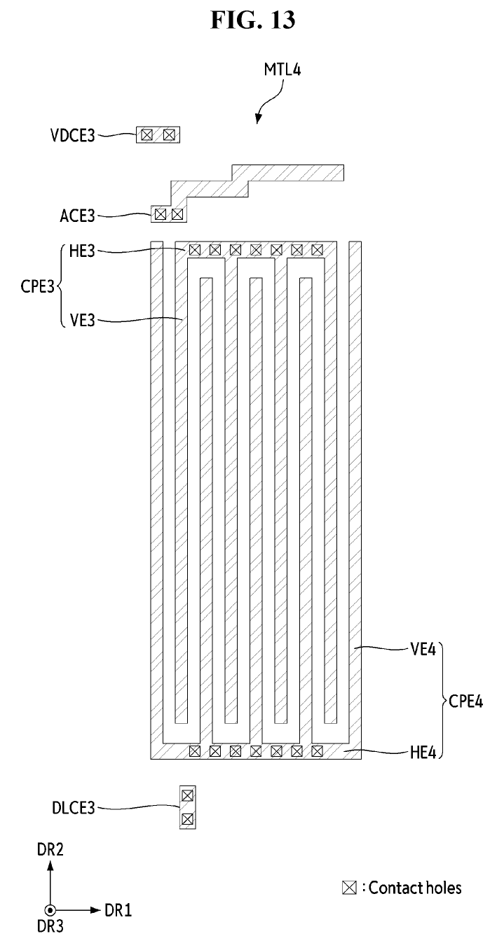

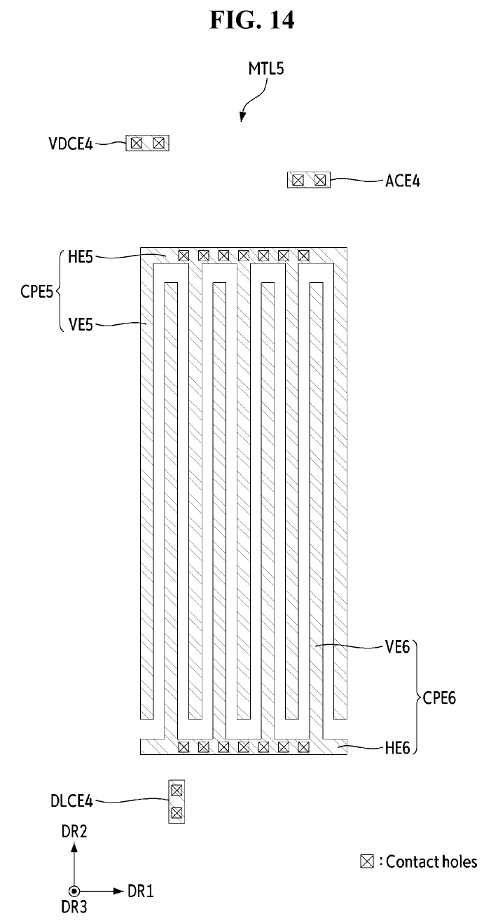

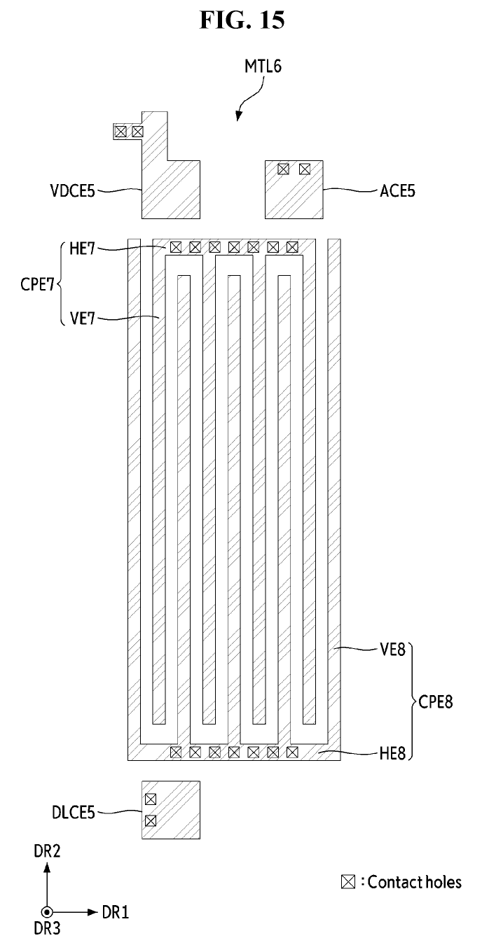

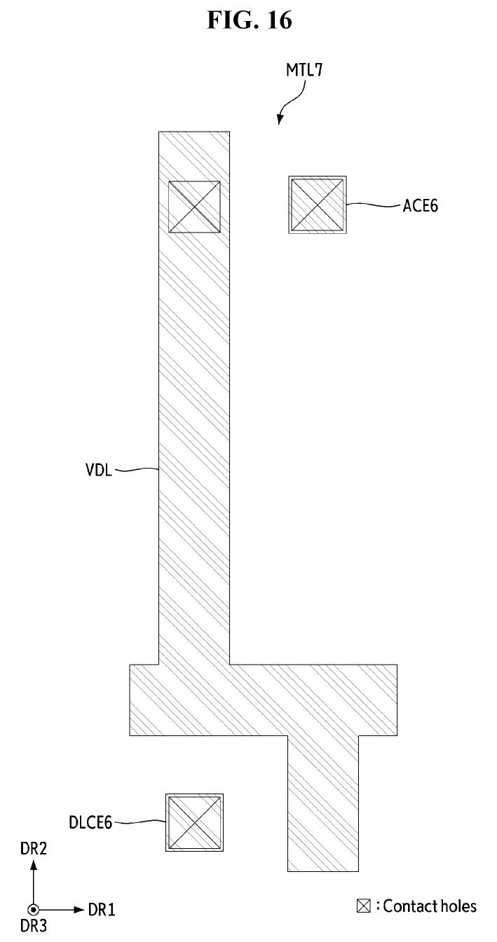

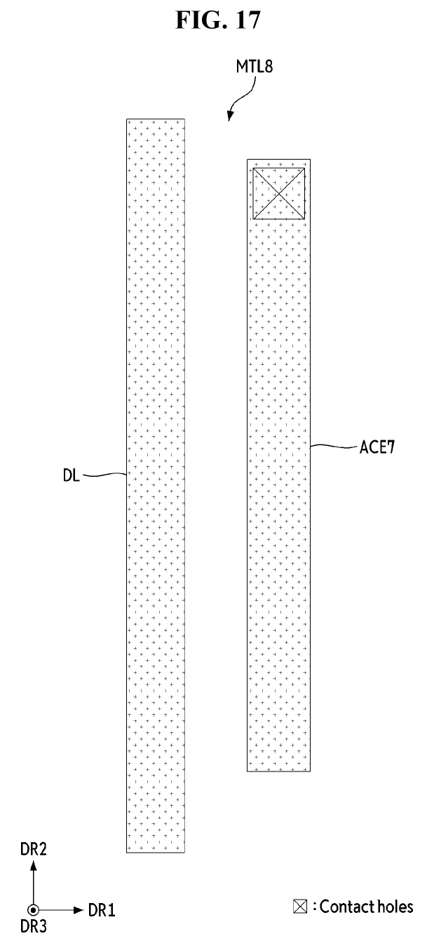

FIG. 8 is a layout view of transistors of the display device according to one or more embodiments, FIG. 9 is a layout view of a first conductive layer MTL1, FIG. 10 is a view for describing a connection relationship between the transistors of FIG. 8 and the first conductive layer MTL1 of FIG. 9, FIG. 11 is a layout view of a second conductive layer MTL2, FIG. 12 is a layout view of a third conductive layer MTL3, FIG. 13 is a layout view of a fourth conductive layer MTL4, FIG. 14 is a layout view of a fifth conductive layer MTL5, FIG. 15 is a layout view of a sixth conductive layer MTL6, FIG. 16 is a layout view of a seventh conductive layer MTL7, and FIG. 17 is a layout view of an eighth conductive layer MTL8.

As illustrated in FIG. 8, a first transistor T1, a second transistor T2, a third transistor T3, a fourth transistor T4, and a fifth transistor T5 may be located on a substrate (e.g., a semiconductor substrate SSUB).

The first transistor T1 may include a first gate electrode GE1, a first source electrode SE1, and a first drain electrode DE1.

The second transistor T2 may include a second gate electrode GE2, a second source electrode SE2, and a second drain electrode DE2.

The third transistor T3 may include a third gate electrode GE3, a third source electrode SE3, and a third drain electrode DE3.

The fourth transistor T4 may include a fourth gate electrode GE4, a fourth source electrode SE4, and a fourth drain electrode DE4.

The fifth transistor T5 may include a fifth gate electrode GE5, a fifth source electrode SE5, and a fifth drain electrode DE5.

In addition, each of the first to fifth transistors T1 to T5 may include a body electrode BE. The body electrode BE of each of the first to fifth transistors T1 to T5 may be integrally formed.

The first conductive layer MTL1 may be located on the first to fifth transistors T1 to T5. As illustrated in FIGS. 9 or 10, the first conductive layer MTL1 may include a body connection electrode BCE, a bias scan line EBL, a first source-drain connection electrode SDCE1, a second source-drain connection electrode SDCE2, a first gate connection electrode GCE1, a fifth gate connection electrode GCE5, a fourth drain connection electrode DCE4, a first source connection electrode SCE1, an emission control line EL, a third drain connection electrode DCE3, a third source connection electrode SCE3, a second drain connection electrode DCE2, a second source connection electrode SCE2, and a write scan line GWL.

The body connection electrode BCE may be connected to the body electrode BE through a contact hole (e.g., a via electrode) in the insulating layer.

The bias scan line EBL may be connected to the fourth gate electrode GE4 through a contact hole (e.g., a via electrode) in the insulating layer.

One side of the first source-drain connection electrode SDCE1 may be connected to the fourth source electrode SE4 through a contact hole (e.g., a via electrode) in the insulating layer, and the other side of the first source-drain connection electrode SDCE1 may be connected to the fifth drain electrode DE5 through a contact hole (e.g., a via electrode) in the insulating layer.

The fourth drain connection electrode DCE4 may be connected to the fourth drain electrode DE4 through a contact hole (e.g., a via electrode) in the insulating layer.

The fifth gate connection electrode GCE5 may be connected to the fifth gate electrode GE5 through a contact hole (e.g., a via electrode) in the insulating layer.

One side of the second source-drain connection electrode SDCE2 may be connected to the fifth source electrode SE5 through a contact hole (e.g., a via electrode) in the insulating layer, and the other side of the second source-drain connection electrode SDCE2 may be connected to the first drain electrode DE1 through a contact hole (e.g., a via electrode) in the insulating layer.

The emission control line EL may be connected to the third gate electrode GE3 through a contact hole (e.g., a via electrode) in the insulating layer.

The third drain connection electrode DCE3 may be connected to the third drain electrode DE3 through a contact hole (e.g., a via electrode) in the insulating layer.

The second drain connection electrode DCE2 may be connected to the second drain electrode DE2 through a contact hole (e.g., a via electrode) in the insulating layer.

The third source connection electrode SCE3 may be connected to the third source electrode SE3 through a contact hole (e.g., a via electrode) in the insulating layer.

The second source connection electrode SCE2 may be connected to the second source electrode SE2 through a contact hole (e.g., a via electrode) in the insulating layer.

The write scan line GWL may be connected to the second gate electrode GE2 through a contact hole (e.g., a via electrode) in the insulating layer.

The second conductive layer MTL2 may be located on the first conductive layer MTL1. As illustrated in FIG. 11, the second conductive layer MTL2 may include a first driving connection electrode VDCE1, a middle connection electrode MCE, a first anode connection electrode ACE1, a reset line REL, an initialization voltage line VIL, a first capacitor connection electrode CCE1, a third source-drain connection electrode SDCE3, a first data connection electrode DLCE1, and a second capacitor connection electrode CCE2.

The first driving connection electrode VDCE1 may be connected to the body connection electrode BCE through a contact hole (e.g., a via electrode) in the insulating layer.

The middle connection electrode MCE may be connected to the bias scan line EBL through a contact hole (e.g., a via electrode) in the insulating layer.

The first anode connection electrode ACE1 may be connected to the first source-drain connection electrode SDCE1 through a contact hole (e.g., a via electrode) in the insulating layer.

The reset line REL may be connected to the fifth gate connection electrode GCE5 through a contact hole (e.g., a via electrode) in the insulating layer.

The initialization voltage line VIL may be connected to the fourth drain connection electrode DCE4 through a contact hole (e.g., a via electrode) in the insulating layer.

One side of the first capacitor connection electrode CCE1 may be connected to the first gate connection electrode GCE1 through a contact hole (e.g., a via electrode) in the insulating layer, and the other side of the first capacitor connection electrode CCE1 may be connected to the second drain connection electrode DCE2 through a contact hole (e.g., a via electrode) in the insulating layer.

One side of the third source-drain connection electrode SDCE3 may be connected to the first source connection electrode SCE1 through a contact hole (e.g., a via electrode) in the insulating layer, and the other side of the third source-drain connection electrode SDCE3 may be connected to the third drain connection electrode DCE3 through a contact hole (e.g., a via electrode) in the insulating layer.

The first data connection electrode DLCE1 may be connected to the second source connection electrode SCE2 through a contact hole (e.g., a via electrode) in the insulating layer.

The second capacitor connection electrode CCE2 may be connected to the third drain connection electrode DCE3 through a contact hole (e.g., a via electrode) in the insulating layer.

The third conductive layer MTL3 may be located on the second conductive layer MTL2. As illustrated in FIG. 12, the third conductive layer MTL3 may include a second driving connection electrode VDCE2, an auxiliary line AXL, a second anode connection electrode ACE2, a first capacitor electrode CPE1, a second capacitor electrode CPE2, and a second data connection electrode DLCE2.

The second driving connection electrode VDCE2 may be connected to the first driving connection electrode VDCE1 through a contact hole (e.g., a via electrode) in the insulating layer.

As illustrated in FIG. 12, in plan view, the auxiliary line AXL may be located between the second driving connection electrode VDCE2 and the second anode connection electrode ACE2. Accordingly, the auxiliary line AXL may be located without interference with another third conductive layer MTL3 (e.g., the second driving connection electrode VDCE2, the second anode connection electrode ACE2, the first capacitor electrode CPE1, the second capacitor electrode CPE2, the second data connection electrode DLCE2) located on the same layer as the auxiliary line AXL.

In addition, in cross-sectional view, the auxiliary line AXL may overlap the bias scan line EBL in the third direction DR3. The auxiliary line AXL may be connected to the middle connection electrode MCE through a contact hole (e.g., a via electrode) in the insulating layer. Accordingly, the auxiliary line AXL may be connected to the bias scan line EBL through the middle connection electrode MCE. Therefore, an area of the bias scan line EBL may increase. In other words, the total area of the bias scan line EBL may be defined as the sum of the area of the bias scan line EBL and the area of the auxiliary line AXL. Therefore, even if a length of the bias scan line EBL in a large-area display device 10 becomes longer, a voltage drop of the bias scan line EBL may be reduced or minimized. Therefore, a distortion of the bias scan signal EB transmitted through the bias scan line EBL may be reduced or minimized.

The second anode connection electrode ACE2 may be connected to the first anode connection electrode ACE1 through a contact hole (e.g., a via electrode) in the insulating layer.

The first capacitor electrode CPE1 may be connected to the first capacitor connection electrode CCE1 through a contact hole (e.g., a via electrode) in the insulating layer. The first capacitor electrode CPE1 may include a first horizontal electrode HE1 extending along a horizontal direction (e.g., the first direction DR1), and at least one first vertical electrode VE1 extending along a vertical direction (e.g., a direction opposite to the second direction DR2 (hereinafter, referred to as a second reverse direction)) from the first horizontal electrode HE1. The first horizontal electrode HE1 and the first vertical electrode VE1 may be formed integrally with each other. The first horizontal electrode HE1 of the first capacitor electrode CPE1 may be connected to the first capacitor connection electrode CCE1 through a contact hole (e.g., a via electrode) in the insulating layer.

The second capacitor electrode CPE2 may be connected to the second capacitor connection electrode CCE2 through a contact hole (e.g., a via electrode) in the insulating layer. The second capacitor electrode CPE2 may include a second horizontal electrode HE2 extending along the horizontal direction (e.g., the first direction DR1) and at least one second vertical electrode VE2 extending along the vertical direction (e.g., the second direction DR2) from the second horizontal electrode HE2. The second horizontal electrode HE2 and the second vertical electrode VE2 may be formed integrally with each other. The second horizontal electrode HE2 of the second capacitor electrode CPE2 may be connected to the second capacitor connection electrode CCE2 through a contact hole (e.g., a via electrode) in the insulating layer. A plurality of second vertical electrodes VE2 and a plurality of first vertical electrodes VE1 may be located along the first direction DR1. In this case, the second vertical electrodes VE2 and the first vertical electrodes VE1 may be alternately located along the first direction DR1. The second vertical electrode VE2 and the first vertical electrode VE1, which are adjacent to each other, may be spaced apart from each other by a distance.

The second data connection electrode DLCE2 may be connected to the first data connection electrode DLCE1 through a contact hole (e.g., a via electrode) in the insulating layer.

The fourth conductive layer MTL4 may be located on the third conductive layer MTL3. As illustrated in FIG. 13, the fourth conductive layer MTL4 may include a third driving connection electrode VDCE3, a third anode connection electrode ACE3, a third capacitor electrode CPE3, a fourth capacitor electrode CPE4, and a third data connection electrode DLCE3.

The third driving connection electrode VDCE3 may be connected to the second driving connection electrode VDCE2 through a contact hole (e.g., a via electrode) in the insulating layer.

The third anode connection electrode ACE3 may be connected to the second anode connection electrode ACE2 through a contact hole (e.g., a via electrode) in the insulating layer.

The third capacitor electrode CPE3 may be connected to the first capacitor electrode CPE1 through a contact hole (e.g., a via electrode) in the insulating layer. The third capacitor electrode CPE3 may include a third horizontal electrode HE3 extending along the horizontal direction (e.g., the first direction DR1) and at least one third vertical electrode VE3 extending along the vertical direction (e.g., the second reverse direction) from the third horizontal electrode HE3. The third horizontal electrode HE3 and the third vertical electrode VE3 may be formed integrally with each other. The third horizontal electrode HE3 of the third capacitor electrode CPE3 may be connected to the first capacitor electrode CPE1 through a contact hole (e.g., a via electrode) in the insulating layer.

The fourth capacitor electrode CPE4 may be connected to the second capacitor electrode CPE2 through a contact hole (e.g., a via electrode) in the insulating layer. The fourth capacitor electrode CPE4 may include a fourth horizontal electrode HE4 extending along the horizontal direction (e.g., the first direction DR1) and at least one fourth vertical electrode VE4 extending along the vertical direction (e.g., the second direction DR2) from the fourth horizontal electrode HE4. The fourth horizontal electrode HE4 and the fourth vertical electrode VE4 may be formed integrally with each other. The fourth horizontal electrode HE4 of the fourth capacitor electrode CPE4 may be connected to the second capacitor electrode CPE2 through a contact hole (e.g., a via electrode) in the insulating layer. A plurality of fourth vertical electrodes VE4 and a plurality of fourth vertical electrodes VE4 may be located along the first direction DR1. In this case, the fourth vertical electrodes VE4 and the third vertical electrodes VE3 may be alternately located along the first direction DR1. The fourth vertical electrode VE4 and the third vertical electrode VE3, which are adjacent to each other, may be spaced apart from each other by a distance.

The third data connection electrode DLCE3 may be connected to the second data connection electrode DLCE2 through a contact hole (e.g., a via electrode) in the insulating layer.

The fifth conductive layer MTL5 may be located on the fourth conductive layer MTL4. As illustrated in FIG. 14, the fifth conductive layer MTL5 may include a fourth driving connection electrode VDCE4, a fourth anode connection electrode ACE4, a fifth capacitor electrode CPE5, a sixth capacitor electrode CPE6, and a fourth data connection electrode DLCE4.

The fourth driving connection electrode VDCE4 may be connected to the third driving connection electrode VDCE3 through a contact hole (e.g., a via electrode) in the insulating layer.

The fourth anode connection electrode ACE4 may be connected to the third anode connection electrode ACE3 through a contact hole (e.g., a via electrode) in the insulating layer.

The fifth capacitor electrode CPE5 may be connected to the third capacitor electrode CPE3 through a contact hole (e.g., a via electrode) in the insulating layer. The fifth capacitor electrode CPE5 may include a fifth horizontal electrode HE5 extending along the horizontal direction (e.g., the first direction DR1) and at least one fifth vertical electrode VE5 extending along the vertical direction (e.g., the second reverse direction) from the fifth horizontal electrode HE5. The fifth horizontal electrode HE5 and the fifth vertical electrode VE5 may be formed integrally with each other. The fifth horizontal electrode HE5 of the fifth capacitor electrode CPE5 may be connected to the third capacitor electrode CPE3 through a contact hole (e.g., a via electrode) in the insulating layer.

The sixth capacitor electrode CPE6 may be connected to the fourth capacitor electrode CPE4 through a contact hole (e.g., a via electrode) in the insulating layer. The sixth capacitor electrode CPE6 may include a sixth horizontal electrode HE6 extending along the horizontal direction (e.g., the first direction DR1) and at least one sixth vertical electrode VE6 extending along the vertical direction (e.g., the second direction DR2) from the sixth horizontal electrode HE6. The sixth horizontal electrode HE6 and the sixth vertical electrode VE6 may be formed integrally with each other. The sixth horizontal electrode HE6 of the sixth capacitor electrode CPE6 may be connected to the fourth capacitor electrode CPE4 through a contact hole (e.g., a via electrode) in the insulating layer. A plurality of sixth vertical electrodes VE6 and a plurality of fifth vertical electrodes VE5 may be located along the first direction DR1. In this case, the sixth vertical electrodes VE6 and the fifth vertical electrodes VE5 may be alternately located along the first direction DR1. The sixth vertical electrode VE6 and the fifth vertical electrode VE5, which are adjacent to each other, may be spaced apart from each other by a distance.

The fourth data connection electrode DLCE4 may be connected to the third data connection electrode DLCE3 through a contact hole (e.g., a via electrode) in the insulating layer.

The sixth conductive layer MTL6 may be located on the fifth conductive layer MTL5. As illustrated in FIG. 15, the sixth conductive layer MTL6 may include a fifth driving connection electrode VDCE5, a fifth anode connection electrode ACE5, a seventh capacitor electrode CPE7, an eighth capacitor electrode CPE8, and a fifth data connection electrode DLCE5.

The fifth driving connection electrode VDCE5 may be connected to the fourth driving connection electrode VDCE4 through a contact hole (e.g., a via electrode) in the insulating layer.

The fifth anode connection electrode ACE5 may be connected to the fourth anode connection electrode ACE4 through a contact hole (e.g., a via electrode) in the insulating layer.

The seventh capacitor electrode CPE7 may be connected to the fifth capacitor electrode CPE5 through a contact hole (e.g., a via electrode) in the insulating layer. The seventh capacitor electrode CPE7 may include a seventh horizontal electrode HE7 extending along the horizontal direction (e.g., the first direction DR1) and at least one seventh vertical electrode VE7 extending along the vertical direction (e.g., the second reverse direction) from the seventh horizontal electrode HE7. The seventh horizontal electrode HE7 and the seventh vertical electrode VE7 may be formed integrally with each other. The seventh horizontal electrode HE7 of the seventh capacitor electrode CPE7 may be connected to the fifth capacitor electrode CPE5 through a contact hole (e.g., a via electrode) in the insulating layer.

The eighth capacitor electrode CPE8 may be connected to the sixth capacitor electrode CPE6 through a contact hole (e.g., a via electrode) in the insulating layer. The eighth capacitor electrode CPE8 may include an eighth horizontal electrode HE8 extending along the horizontal direction (e.g., the first direction DR1) and at least one eighth vertical electrode VE8 extending along the vertical direction (e.g., the second direction DR2) from the eighth horizontal electrode HE8. The eighth horizontal electrode HE8 and the eighth vertical electrode VE8 may be formed integrally with each other. The eighth horizontal electrode HE8 of the eighth capacitor electrode CPE8 may be connected to the sixth capacitor electrode CPE6 through a contact hole (e.g., a via electrode) in the insulating layer. A plurality of eighth vertical electrodes VE8 and a plurality of seventh vertical electrodes VE7 may be located along the first direction DR1. In this case, the eighth vertical electrodes VE8 and the seventh vertical electrodes VE7 may be alternately located along the first direction DR1. The eighth vertical electrode VE8 and the seventh vertical electrode VE7, which are adjacent to each other, may be spaced apart from each other by a distance.

The above-described capacitor CP may include the first to eighth capacitor electrodes CPE1 to CPE8. In this case, the first, third, fifth, and seventh capacitor electrodes CPE1, CPE3, CPE5, and CPE7 may correspond to electrodes on one side of the capacitor CP (e.g., electrodes on one side of the capacitor CP connected to the first node N1), and the second, fourth, sixth, and eighth capacitor electrodes CPE2, CPE4, CPE6, and CPE8 may correspond to electrodes on the other side of the capacitor CP (e.g., electrodes on the other side of the capacitor CP connected to the second node N2).

The fifth data connection electrode DLCE5 may be connected to the fourth data connection electrode DLCE4 through a contact hole (e.g., a via electrode) in the insulating layer.

The seventh conductive layer MTL7 may be located on the sixth conductive layer MTL6. As illustrated in FIG. 16, the seventh conductive layer MTL7 may include a driving voltage line VDL, a sixth anode connection electrode ACE6, and a sixth data connection electrode DLCE6.

The driving voltage line VDL may be connected to the fifth driving connection electrode VDCE5 through a contact hole (e.g., a via electrode) in the insulating layer.

The sixth anode connection electrode ACE6 may be connected to the fifth anode connection electrode ACE5 through a contact hole (e.g., a via electrode) in the insulating layer.

The sixth data connection electrode DLCE6 may be connected to the fifth data connection electrode DLCE5 through a contact hole (e.g., a via electrode) in the insulating layer.

The eighth conductive layer MTL8 may be located on the seventh conductive layer MTL7. As illustrated in FIG. 17, the eighth conductive layer MTL8 may include a data line DL and a seventh anode connection electrode ACE7.

The data line DL may be connected to the sixth data connection electrode DLCE6 through a contact hole (e.g., a via electrode) in the insulating layer.

The seventh anode connection electrode ACE7 may be connected to the sixth anode connection electrode ACE6 through a contact hole (e.g., a via electrode) in the insulating layer.

The seventh anode connection electrode ACE7 may be connected to the first electrode through the above-described reflective electrode layer RL.

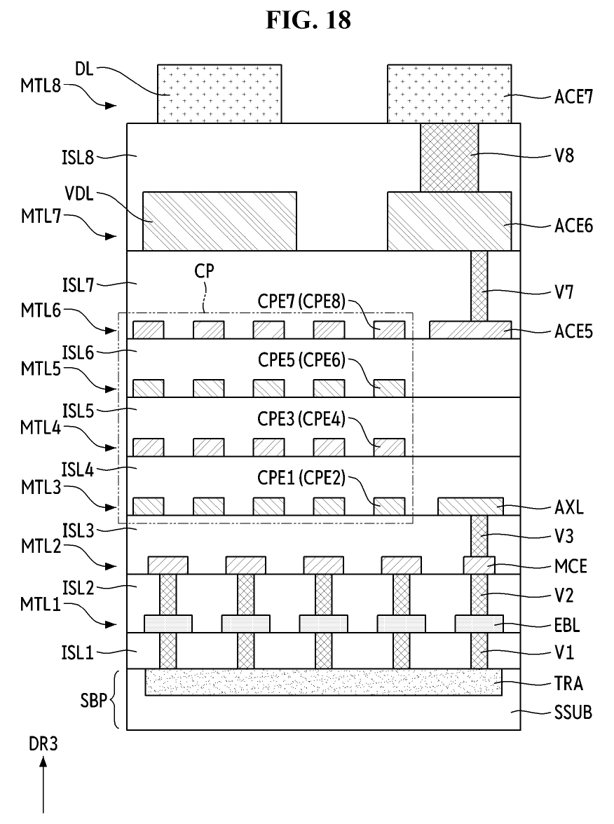

FIG. 18 is a cross-sectional view of the display device 10 according to one or more embodiments. For example, FIG. 18 may be a cross-sectional view of the display device 10 including the first to fifth transistors T1 to T5 and the first to eighth conductive layers MTL1 to MTL8 of FIGS. 8, 9, and 11-17 described above.

As illustrated in FIG. 18, a first insulating layer ISL1 may be located on the semiconductor backplane SBP (as used herein, “located on” may mean “above”). Here, the semiconductor backplane SBP may include a transistor area TRA in which the pixel transistors PTR as described above are located. For example, the first to fifth transistors T1 to T5 of FIG. 8 described above may be located in the transistor area.

The first conductive layer MTL1 including the bias scan line EBL may be located on the first insulating layer ISL1. The bias scan line EBL may be connected to at least one of the pixel transistors in the transistor area TRA through a first via electrode V1 penetrating through the first insulating layer ISL1. For example, the bias scan line EBL may be connected to the fourth gate electrode GE4 of the fourth transistor T4 through the first via electrode V1.

A second insulating layer ISL2 may be located on the first conductive layer MTL1.

The second conductive layer MTL2 including the middle connection electrode MCE may be located on the second insulating layer ISL2. The middle connection electrode MCE may be connected to the bias scan line EBL through a second via electrode V2 penetrating through the second insulating layer ISL2.

A third insulating layer ISL3 may be located on the second conductive layer MTL2.

The third conductive layer MTL3 including the first capacitor electrode CPE1, the second capacitor electrode CPE2, and the auxiliary line AXL may be located on the third insulating layer ISL3. The auxiliary line AXL may be located on the third insulating layer ISL3 to overlap the middle connection electrode MCE and the bias scan line EBL. The auxiliary line AXL may be connected to the middle connection electrode MCE through a third via electrode V3 penetrating through the third insulating layer ISL3. Accordingly, the auxiliary line AXL and the bias scan line EBL located on different layers in the third direction DR3 may be connected to each other. For example, the auxiliary line AXL and the bias scan line EBL located on different layers in the third direction DR3 may be connected to each other through the middle connection electrode MCE located between the auxiliary line AXL and the bias scan line EBL. Therefore, an area of the bias scan line EBL may increase. In other words, the total area of the bias scan line EBL may be defined as the sum of the area of the bias scan line EBL and the area of the auxiliary line AXL. The total area of the bias scan line EBL may further include an area of the middle connection electrode MCE. Therefore, even if a length of the bias scan line EBL in a large-area display device 10 becomes longer, a voltage drop of the bias scan line EBL may be reduced or minimized. Therefore, a distortion of the bias scan signal EB transmitted through the bias scan line EBL may be reduced or minimized.

A fourth insulating layer ISL4 may be located on the third conductive layer MTL3.

The fourth conductive layer MTL4 including the third capacitor electrode CPE3 and the fourth capacitor electrode CPE4 may be located on the fourth insulating layer ISL4. The third capacitor electrode CPE3 may overlap one of the first capacitor electrode CPE1 or the second capacitor electrode CPE2, and the fourth capacitor electrode CPE4 may overlap the other one of the first capacitor electrode CPE1 or the second capacitor electrode CPE2. A fourth via electrode penetrating through the fourth insulating layer ISL4 may be located in the fourth insulating layer ISL4.

A fifth insulating layer ISL5 may be located on the fourth conductive layer MTL4.

The fifth conductive layer MTL5 including the fifth capacitor electrode CPE5 and the sixth capacitor electrode CPE6 may be located on the fifth insulating layer ISL5. The fifth capacitor electrode CPE5 may overlap one of the third capacitor electrode CPE3 or the fourth capacitor electrode CPE4, and the sixth capacitor electrode CPE6 may overlap the other one of the third capacitor electrode CPE3 or the fourth capacitor electrode CPE4. A fifth via electrode penetrating through the fifth insulating layer ISL5 may be located in the fifth insulating layer ISL5.

A sixth insulating layer ISL6 may be located on the fifth conductive layer MTL5.

The sixth conductive layer MTL6 including the seventh capacitor electrode CPE7, the eighth capacitor electrode CPE8, and the fifth anode connection electrode ACE5 may be located on the sixth insulating layer ISL6. The seventh capacitor electrode CPE7 may overlap one of the fifth capacitor electrode CPE5 or the sixth capacitor electrode CPE6, and the eighth capacitor electrode CPE8 may overlap the other one of the fifth capacitor electrode CPE5 or the sixth capacitor electrode CPE6. A sixth via electrode penetrating through the sixth insulating layer ISL6 may be located in the sixth insulating layer ISL6.

A seventh insulating layer ISL7 may be located on the sixth conductive layer MTL6.

The seventh conductive layer MTL7 including the driving voltage line VDL and the sixth anode connection electrode ACE6 may be located on the seventh insulating layer ISL7. The sixth anode connection electrode ACE6 may be connected to the fifth anode connection electrode ACE5 through a seventh via electrode V7 penetrating through the seventh insulating layer ISL7.

An eighth insulating layer ISL8 may be located on the seventh conductive layer MTL7.

The eighth conductive layer MTL8 including the data line DL and the seventh anode connection electrode ACE7 may be located on the eighth insulating layer ISL8. The seventh anode connection electrode ACE7 may be connected to the sixth anode connection electrode ACE6 through an eighth via electrode V8 penetrating through the eighth insulating layer ISL8.

The sixth anode connection electrode ACE6 may be connected to the first electrode AND through a ninth via electrode VA9 located thereon, a reflective electrode layer RL on the ninth via electrode VA9, and a tenth via electrode VA10 on the reflective electrode layer RL.

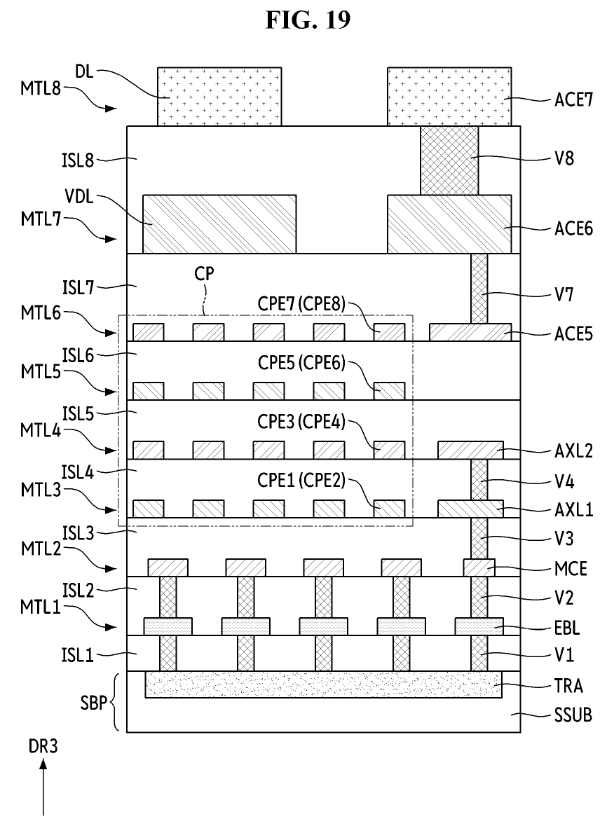

FIG. 19 is a cross-sectional view of a display device according to one or more other embodiments. For example, FIG. 19 may be a cross-sectional view of the display device 10 including the first to fifth transistors T1 to T5 and the first to eighth conductive layers MTL1 to MTL8 of FIGS. 8, 9, and 11-17, described above.

The display device 10 of FIG. 19 is different from the display device of FIG. 18 in that the display device 10 of FIG. 19 includes two auxiliary lines AXL1 and AXL2, and such a difference will be mainly described as follows.

As illustrated in FIG. 19, the display device 10 may include a plurality of auxiliary lines AXL1 and AXL2 located on different layers in the third direction DR3. For example, the display device 10 may include a first auxiliary line AXL1, and a second auxiliary line AXL2 located on the first auxiliary line AXL1.

The plurality of auxiliary lines AXL1 and AXL2 may be connected to each other. For example, the first auxiliary line AXL1 and the second auxiliary line AXL2 may be connected to each other through the fourth via electrode V4.

The plurality of auxiliary lines AXL1 and AXL2 may be connected to the bias scan line EBL. Accordingly, the total area of the bias scan line EBL may be further increased. Therefore, even if a length of the bias scan line EBL in a large-area display device 10 becomes longer, a voltage drop of the bias scan line EBL may be reduced or minimized. Therefore, a distortion of the bias scan signal EB transmitted through the bias scan line EBL may be reduced or minimized.

Because the first auxiliary line AXL1 may be identical to the auxiliary line AXL of FIG. 18 described above, the description of the first auxiliary line AXL1 refers to the description of the auxiliary line AXL of FIG. 18 described above.

The second auxiliary line AXL2 may be located on the first auxiliary line AXL1. For example, the second auxiliary line AXL2 may be located on the fourth insulating layer ISL4 to overlap the first auxiliary line AXL1. The second auxiliary line AXL2 may be connected to the first auxiliary line AXL1 through the fourth via electrode V4 penetrating through the fourth insulating layer ISL4.

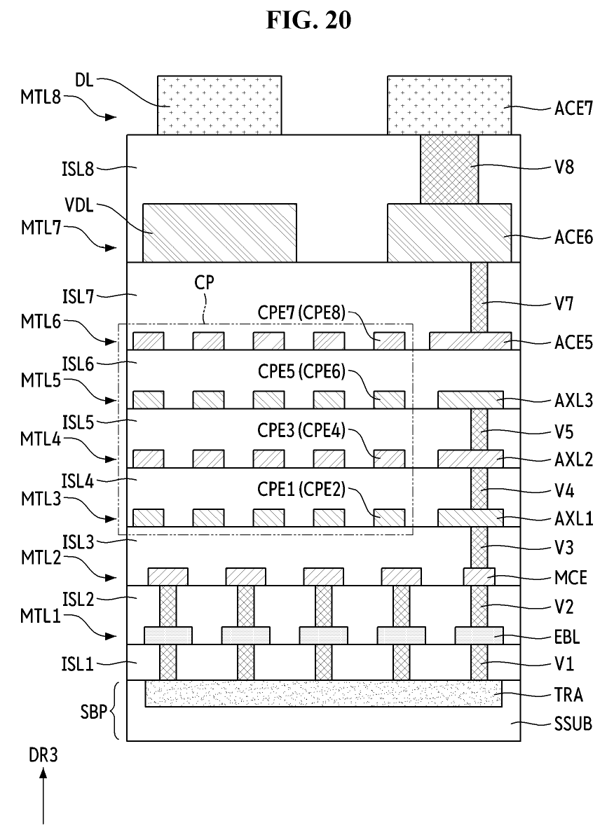

FIG. 20 is a cross-sectional view of a display device 10 according to one or more other embodiments. For example, FIG. 20 may be a cross-sectional view of the display device 10 including the first to fifth transistors T1 to T5 and the first to eighth conductive layers MTL1 to MTL8 of FIGS. 8, 9, and 11-17, described above.

The display device 10 of FIG. 20 is different from the display device 10 of FIG. 18 in that the display device 10 of FIG. 20 includes three auxiliary lines AXL1, AXL2, and AXL3, and such a difference will be mainly described as follows.

As illustrated in FIG. 20, the display device 10 may include a plurality of auxiliary lines AXL1, AXL2, and AXL3 located on different respective layers in the third direction DR3. For example, the display device 10 may include a first auxiliary line AXL1, a second auxiliary line AXL2 located on the first auxiliary line AXL1, and a third auxiliary line AXL3 located on the second auxiliary line AXL2.

The plurality of auxiliary lines AXL1, AXL2, and AXL3 may be connected to each other. For example, the first auxiliary line AXL1 and the second auxiliary line AXL2 may be connected to each other through the fourth via electrode V4, and the second auxiliary line AXL2 and the third auxiliary line AXL3 may be connected to each other through the fifth via electrode V5.

The plurality of auxiliary lines AXL1, AXL2, and AXL3 may be connected to the bias scan line EBL. Accordingly, the total area of the bias scan line EBL may be further increased. Therefore, even if a length of the bias scan line EBL in a large-area display device becomes longer, a voltage drop of the bias scan line EBL may be reduced or minimized. Therefore, a distortion of the bias scan signal EB transmitted through the bias scan line EBL may be reduced or minimized.

Because the first auxiliary line AXL1 is identical to the auxiliary line AXL of FIG. 18 described above, the description of the first auxiliary line AXL1 refers to the description of the auxiliary line AXL of FIG. 18 described above.

Because the second auxiliary line AXL2 is identical to the second auxiliary line AXL2 of FIG. 19 described above, the description of the second auxiliary line AXL2 refers to the description of the second auxiliary line AXL2 of FIG. 19 described above.

The third auxiliary line AXL3 may be located on the second auxiliary line AXL2. For example, the third auxiliary line AXL3 may be located on the fifth insulating layer ISL5 to overlap the second auxiliary line AXL2. The third auxiliary line AXL3 may be connected to the second auxiliary line AXL2 through the fifth via electrode V5 penetrating through the fifth insulating layer ISL5.

According to one or more embodiments, in addition to the above-described bias scan line EBL, at least one other scan line may have the same structure as the bias scan line EBL. For example, the display device 10 according to one or more embodiments may further include another auxiliary line located on a different layer from the write scan line GWL and connected to the write scan line GWL through a via electrode.

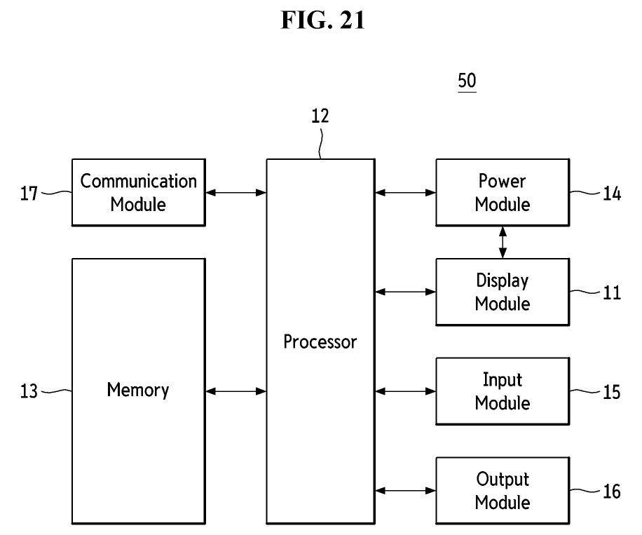

FIG. 21 is a block diagram of an electronic device according to one or more embodiments.

Referring to FIG. 21, an electronic device 50 according to one or more embodiments may include a display module 11, a processor 12, a memory 13, and a power module 14. The electronic device 50 may further include an input module 15, a non-image output module 16, and/or a communication module 17.

The electronic device 50 may output various information in the form of an image through the display module 11. When the processor 12 executes an application stored in the memory 13, image information provided by the application may be provided to the user through the display module 11. The power module 14 may include a power supply module, such as a power adapter or a battery device, and a power conversion module that converts power supplied by the power supply module to generate power required for an operation of the electronic device 50. The input module 15 may provide input information to the processor 12 and/or the display module 11. The non-image output module 16 may serve to receive information other than the image received from the processor 12, such as sound, haptics, and light emission, and provide the information to the user. The communication module 17 is a module responsible for transmitting and receiving information between the electronic device 50 and an external device, and may include a receiving unit and a transmitting unit.

At least one of the components of the electronic device 50 described above may be included in the display device according to the above-described embodiments. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device 50 other than the display device.

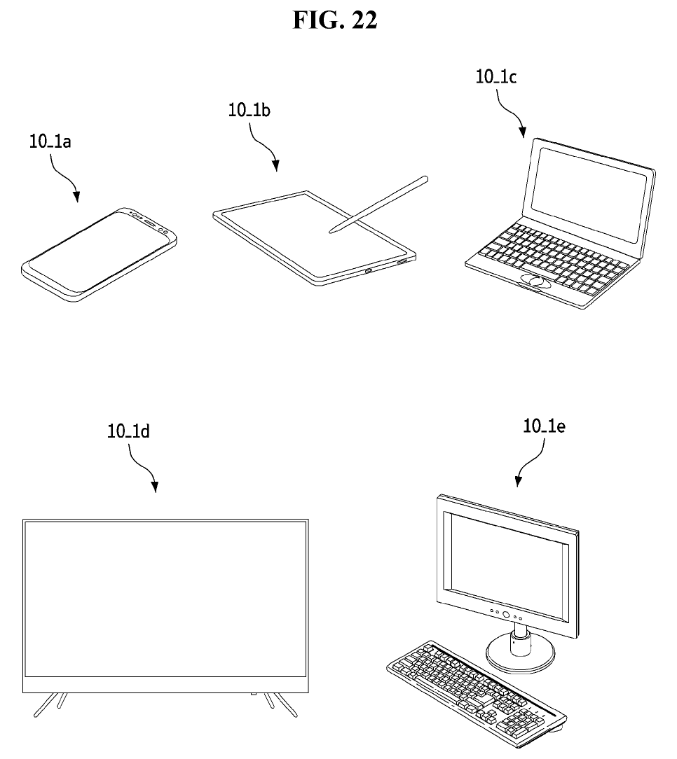

FIGS. 22, 23, and 24,are schematic diagrams of electronic devices according to various embodiments. FIGS. 22-24 illustrate examples of various electronic devices to which the display device 10 according to the embodiments is applied.

FIG. 22 illustrates examples of the electronic devices, including a smartphone 10_1a, a tablet PC 10_1b, a laptop 10_1c, a TV 10_1d, and a desk monitor 10_1e.

The smartphone 10_1a may include an input module, such as a touch sensor and a communication module in addition to the display module 11. The smartphone 10_1a may process information received through the communication module or other input modules and display the information through the display module of the display device.

The tablet PC 10_1b, the laptop 10_1c, the TV 10_1d, and the desk monitor 10_1e also include a display module and an input module similarly to the smartphone 10_1a, and in some cases, may further include a communication module.

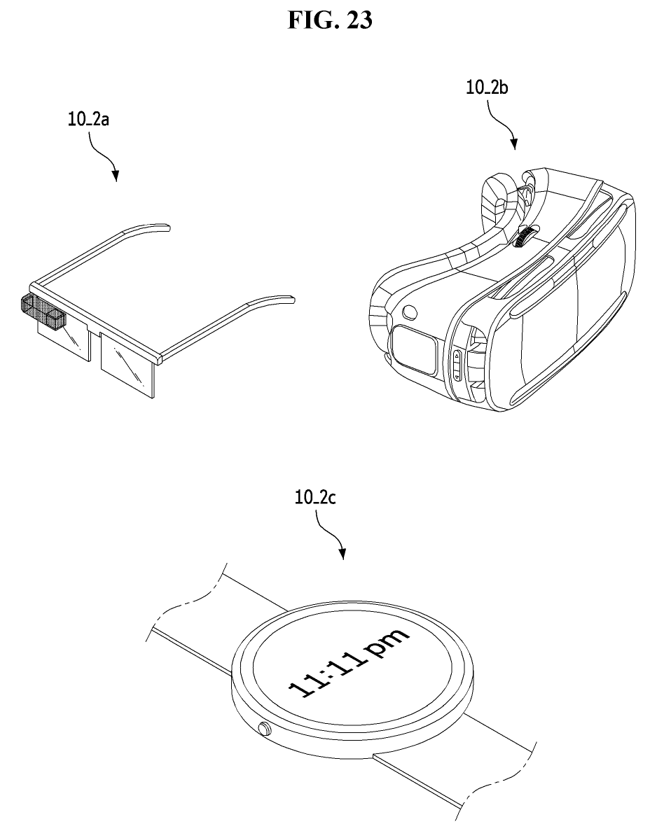

FIG. 23 illustrates a case in which an electronic device including a display module is applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display image and provides the reflected display image to the user's eyes and may provide the user with a virtual reality or augmented reality screen through the display module and the reflector.

The smart watch 10_2c includes a biometric sensor as an input device and may provide the biometric information recognized by the biometric sensor to the user through the display module.

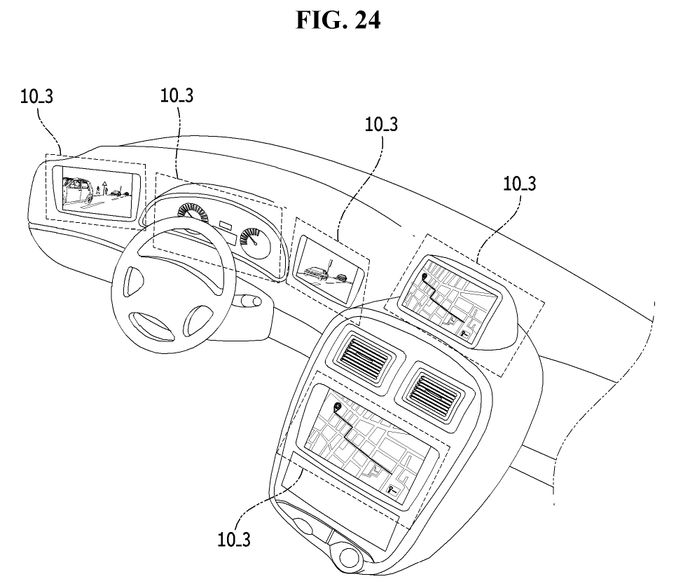

FIG. 24 illustrates an example in which an electronic device including a display module is applied to a vehicle. For example, an electronic device 10_3 may be applied to a dashboard, center fascia, etc. of an automobile, or may be applied to a Center Information Display (CID) located on the dashboard of the automobile or a room mirror display replacing a side mirror.

In concluding the detailed description, those skilled in the art will appreciate that many variations and modifications can be made to the embodiments without substantially departing from the principles of the present disclosure. Therefore, the disclosed embodiments are used in a generic and descriptive sense only and not for purposes of limitation.

What is claimed is:

1. A display device comprising:
a substrate;
a transistor above the substrate;
a scan line connected to the transistor;
a first electrode above the scan line;
a light-emitting stack above the first electrode;
a second electrode above the light-emitting stack; and
an auxiliary line at a different layer from the scan line, and connected to the scan line.

2. The display device of claim 1, wherein the auxiliary line is above the scan line.

3. The display device of claim 2, further comprising:
a first insulating layer above the transistor;
a second insulating layer above the first insulating layer; and
a third insulating layer above the second insulating layer.

4. The display device of claim 3, wherein the scan line is above the first insulating layer, and
wherein the auxiliary line is above the third insulating layer to overlap the scan line.

5. The display device of claim 4, further comprising a middle connection electrode above the second insulating layer between the scan line and the auxiliary line, and connected to the scan line and to the auxiliary line.

6. The display device of claim 5, further comprising:
a first via electrode penetrating through the first insulating layer and connected to a gate electrode of the transistor and to the scan line;
a second via electrode penetrating through the second insulating layer and connected to the scan line and to the middle connection electrode; and
a third via electrode penetrating through the third insulating layer and connected to the middle connection electrode and to the auxiliary line.

7. The display device of claim 1, further comprising a capacitor electrode at a same layer as the auxiliary line.

8. The display device of claim 1, further comprising a driving connection electrode and an anode connection electrode at a same layer as the auxiliary line.

9. The display device of claim 8, wherein the auxiliary line is between the driving connection electrode and the anode connection electrode in plan view.

10. The display device of claim 8, further comprising a capacitor electrode at the same layer as the auxiliary line.

11. The display device of claim 1, wherein the auxiliary line comprises a plurality of auxiliary lines at different respective layers.

12. The display device of claim 11, further comprising:
a first insulating layer above the transistor;
a second insulating layer above the first insulating layer;
a third insulating layer above the second insulating layer; and
a fourth insulating layer above the third insulating layer.

13. The display device of claim 12, wherein the scan line is above the first insulating layer, and
wherein the auxiliary line comprises:
a first auxiliary line above the third insulating layer to overlap the scan line; and
a second auxiliary line above the fourth insulating layer to overlap the first auxiliary line.

14. The display device of claim 13, further comprising a middle connection electrode above the second insulating layer between the scan line and the first auxiliary line, and connected to the scan line and to the first auxiliary line.

15. The display device of claim 14, further comprising:
a first via electrode penetrating through the first insulating layer and connected to a gate electrode of the transistor and to the scan line;
a second via electrode penetrating through the second insulating layer and connected to the scan line and to the middle connection electrode;
a third via electrode penetrating through the third insulating layer and connected to the middle connection electrode and to the first auxiliary line; and
a fourth via electrode penetrating through the fourth insulating layer and connected to the first auxiliary line and to the second auxiliary line.

16. The display device of claim 14, further comprising a fifth insulating layer above the fourth insulating layer.

17. The display device of claim 16, wherein the auxiliary line further comprises a third auxiliary line above the fifth insulating layer to overlap the second auxiliary line.

18. The display device of claim 17, further comprising a fifth via electrode penetrating through the fifth insulating layer and connected to the second auxiliary line and to the third auxiliary line.

19. An electronic device comprising:
a display device comprising:
a substrate;
a transistor above the substrate;
a scan line connected to the transistor;
a first electrode above the scan line;
a light-emitting stack above the first electrode;
a second electrode above the light-emitting stack; and
an auxiliary line at a different layer from the scan line and connected to the scan line.

20. The electronic device of claim 19, wherein the electronic device comprises a smartphone, a tablet, a laptop, a TV, a desk monitor, a smart glasses, a smart watch, a head-mounted display, or a vehicle.
